(19) United States
(12) Patent Application Publication
(10) Pub. No.: US 2026/0204676 A1
(43) Pub. Date: Jul. 16, 2026

(54) SYSTEMS AND METHODS FOR BATTERY THERMAL MANAGEMENT SYSTEM SELECTION AND CONTROL

(71) Applicants: Arizona Board of Regents on Behalf of Arizona State University, Tempe, AZ (US); Mansoura University, Mansoura (EG); Damietta University, Damietta El-Gadeeda City (EG)

(72) Inventors: Moustafa Amer, Mansoura (EG); Mohamed Salem, Mansoura (EG); Arunachala Kannan, Gilbert, AZ (US); Ahmed Hamed, Mansoura (EG); Mahmoud Shouman, Mansoura (EG)

(21) Appl. No.: 19/447,882

(22) Filed: Jan. 13, 2026

Related U.S. Application Data
(60) Provisional application No. 63/744,764, filed on Jan. 13, 2025.

(51) Int. Cl. H01M 10/633; H01M 10/44; H01M 10/613; H01M 10/635

(52) U.S. Cl. CPC H01M 10/633; H01M 10/443; H01M 10/613; H01M 10/635

(57) ABSTRACT

A computer-implemented system constructs an equivalent circuit model of a battery from hybrid pulse power characterization data and continuous discharge data. The system accesses thermal limit values for discharge, including a maximum battery surface temperature and a maximum surface temperature difference. For each candidate battery thermal management system (BTMS) setting that specifies a cooling temperature setpoint and a cooled-surface cooling length, the system computes battery thermal response values under a cooling boundary condition defined by the candidate setting. Using a relationship between candidate settings and computed responses, the system selects target BTMS setting values that satisfy the thermal limit values and outputs control signals, based on measured battery surface temperature data, to set BTMS operating parameters.

### CROSS-REFERENCE TO RELATED APPLICATIONS

This is a U.S. Non-Provisional Patent Application that claims benefit to U.S. Provisional Patent Application No. 63/744,764 filed Jan. 13, 2025, which is herein incorporated by reference in its entirety.

### FIELD

The present disclosure generally relates to thermal management for energy storage, and in particular, to a system and associated method for assessment of Li-Ion battery thermo-electrochemical performance and battery thermal management requirements.

### BACKGROUND

Current battery thermal management metrics such as maximum temperature and maximum temperature difference depend on ambient temperature and cell geometry and characteristics. Moreover, heat related metrics such as the cell cooling coefficient (CCC) and the CCC for geometry and heat normalization depend on cell capacity and are not generalized in definition because of their dependence on certain cell characteristics at 50% state of charge only.

It is with these observations in mind, among others, that various aspects of the present disclosure were conceived and developed.

### SUMMARY

In one aspect, a system includes a processor in communication with a memory, the memory including instructions executable by the processor to: access information collected during test operation of a battery; and evaluate, using thermo-electrochemicalperformance model that depends on hybrid pulse power characteristics (HPPC) and continuous discharge tests. The system further includes a plurality of thermal performance metrics for the battery based on the information, including: a just adequate cooling area (A_{IDP}) required at an ideal design point (IDP); a cell thermo-electrochemical performance of the battery using a normalized heat generation ratio (NHGR) which determines a ratio of waste to stored energy independent of cell characteristics, and a cell thermal performance of the battery using a cell thermal efficiency that quantifies a capability of the battery to efficiently dissipate generated heat during operation with ideal prescribed objectives at total surface cooling (ηₜₕ) and ideal design point (η_{th-IDP}).

In some aspects, the techniques described herein relate to a computer-implemented method, including: (a) constructing an equivalent circuit model of a battery based on battery characterization data including hybrid pulse power characterization (HPPC) data and continuous discharge data collected during test operation of the battery; (b) accessing prescribed thermal limit data for the battery during discharge with respect to cooling by a battery thermal management system (BTMS), the prescribed thermal limit data including: (i) a maximum allowable battery surface temperature, and (ii) a maximum allowable temperature difference across a battery surface of the battery; (c) generating, for each of a plurality of combinations of BTMS parameters including (i) a cooling temperature setpoint and (ii) a cooled-surface cooling length of the battery, thermal response values for the battery using the equivalent circuit model and a cooling boundary condition target defined by the BTMS parameters; (d) generating, from the thermal response values generated using the equivalent circuit model, a mapping that relates the BTMS parameters to at least a battery surface maximum temperature and a battery surface temperature difference; (e) transforming, based on the mapping, the prescribed thermal limit data into at least one target BTMS parameter value for at least one BTMS parameter of the BTMS; and (f) generating, using measured temperature data measured at the battery surface, one or more control signals that set the at least one BTMS parameter to the at least one target BTMS parameter value.

In some aspects, the techniques described herein relate to a system, including: a processor in communication with a memory and a battery system, the memory including instructions executable by the processor to: (a) construct an equivalent circuit model of a battery based on battery characterization data including hybrid pulse power characterization (HPPC) data and continuous discharge data collected during test operation of the battery; (b) access prescribed thermal limit data for the battery during discharge with respect to cooling by a battery thermal management system (BTMS), the prescribed thermal limit data including: (i) a maximum allowable battery surface temperature, and (ii) a maximum allowable temperature difference across a battery surface of the battery; (c) generate, for each of a plurality of combinations of BTMS parameters including (i) a cooling temperature setpoint and (ii) a cooled-surface cooling length of the battery, thermal response values for the battery using the equivalent circuit model and a cooling boundary condition target defined by the BTMS parameters; (d) generate, from the thermal response values generated using the equivalent circuit model, a mapping that relates the BTMS parameters to at least a battery surface maximum temperature and a battery surface temperature difference; (e) transform, based on the mapping, the prescribed thermal limit data into at least one target BTMS parameter value for at least one BTMS parameter of the BTMS; and (f) generate, using measured temperature data measured at the battery surface, one or more control signals that set the at least one BTMS parameter to the at least one target BTMS parameter value.

In some aspects, the techniques described herein relate to one or more non-transitory computer-readable medium having computer-readable instructions stored therein which, when executed by one or more processors, cause the one or more processors to: (a) construct an equivalent circuit model of a battery based on battery characterization data including hybrid pulse power characterization (HPPC) data and continuous discharge data collected during test operation of the battery; (b) access prescribed thermal limit data for the battery during discharge with respect to cooling by a battery thermal management system (BTMS), the prescribed thermal limit data including: (i) a maximum allowable battery surface temperature, and (ii) a maximum allowable temperature difference across a battery surface of the battery; (c) generate, for each of a plurality of combinations of BTMS parameters including (i) a cooling temperature setpoint and (ii) a cooled-surface cooling length of the battery, thermal response values for the battery using the equivalent circuit model and a cooling boundary condition target defined by the BTMS parameters; (d) generate, from the thermal response values generated using the equivalent circuit model, a mapping that relates the BTMS parameters to at least a battery surface maximum temperature and a battery surface temperature difference; (e) transform, based on the mapping, the prescribed thermal limit data into at least one target BTMS parameter value for at least one BTMS parameter of the BTMS; and (f) generate, using measured temperature data measured at the battery surface, one or more control signals that set the at least one BTMS parameter to the at least one target BTMS parameter value.

### BRIEF DESCRIPTION OF THE DRAWINGS

FIG. 1 is a schematic diagram illustrating example battery subsystems and interactions, including a cell thermo-electrochemical system, a cell thermal system, a battery thermal management system (BTMS), and ambient heat dissipation.

FIG. 2 is a block diagram of an example computing device including a processor in communication with a memory storing thermal management evaluation and/or control routines, and further including one or more interfaces for communicating with external devices and/or networks.

FIG. 3 is a schematic diagram of an example system including a battery having one or more temperature sensors, a BTMS configured to cool the battery, and a computing device configured to receive battery characterization data and measured temperature data and to generate control signals for setting one or more BTMS operating parameters.

FIG. 4 is a flow diagram of an example computer-implemented method for (i) constructing an equivalent circuit model (ECM) of a battery from characterization data, (ii) generating thermal response values across combinations of BTMS parameter values, (iii) generating a mapping relating BTMS parameters to thermal response quantities, (iv) transforming prescribed thermal limit data into target BTMS parameter values, and (v) generating control signals for operating the BTMS.

FIG. 5A is a dataflow diagram illustrating example inputs, intermediate data, and outputs associated with constructing an ECM, defining a BTMS parameter space (including candidate BTMS settings), generating thermal response values, and generating a mapping relating BTMS parameters to one or more thermal response quantities.

FIG. 5B is a dataflow diagram illustrating transforming prescribed thermal limit data, based on a mapping, into target BTMS settings; generating control signals for the BTMS based on the target BTMS settings; and providing one or more outputs to a user interface.

FIG. 6 is a schematic diagram of an example ECM of a battery, including an open-circuit voltage source and electrical elements including a series resistance and one or more RC polarization branches, for producing a terminal voltage.

FIG. 7 is a representation of example experimental test equipment, including (a) a full experimental setup and (b) a cell positioned within a thermal chamber with a temperature sensor.

FIGS. 8A-8B illustrate an example cell model, respectively showing a front view of the cell and a mesh sample for a numerical analysis model of the cell domain.

FIG. 9 is a schematic representation of a battery surface including a cooled portion having a length corresponding to a cooling length, for use in applying a cooling boundary condition to a portion of the battery surface.

FIG. 10 is a graph illustrating a mesh dependency study of a 1 C continuous discharge for an INR21700-50 cell at a 25° C. ambient temperature.

FIG. 11 is a graph illustrating a time dependency test for an INR21700-50 cell at a 1 C continuous discharge and a 25° C. ambient temperature.

FIG. 12 is a graph illustrating a hybrid pulse power characterization (HPPC) test used for parameter estimation at 25° C., 45° C., and 55° C. ambient temperatures.

FIG. 13 is a graph illustrating an urban dynamometer driving schedule (UDDS) cycle used for parameter validation of electrical behavior at 25° C.

FIG. 14 is a graph illustrating thermal behavior during a rest period after a 1 C continuous discharge.

FIG. 15 is a graph illustrating ECM thermal behavior validation of an INR21700-50E cell for various continuous discharge rates (0.5 C, 1 C, and 2 C) and at various ambient temperatures (25° C., 45° C., and 55° C.).

FIG. 16 is a graph illustrating thermal behaviors of an INR21700-50E cell for a 1 C continuous discharge at different ambient temperatures (25° C., 45° C., and 55° C.).

FIG. 17 illustrates temperature contours of an INR21700-50E cell for (a) an ideal design point (IDP) case and (b) a total surface cooling case.

FIG. 18 illustrates response surfaces of cooling lengths and cooling temperatures for an INR21700-50E cell at the end of a 1 C continuous discharge, including response surfaces for (a) maximum temperature, (b) maximum temperature difference, (c) cooling coefficient (CCC), (d) geometry-normalized cooling coefficient (CCC_{GN}), and (e) heat dissipation rate.

FIG. 19 illustrates response surfaces of cooling lengths and cooling temperatures for an NCR18650PF cell at the end of a 1 C continuous discharge, including response surfaces for (a) maximum temperature, (b) maximum temperature difference, (c) cooling coefficient (CCC), (d) geometry-normalized cooling coefficient (CCC_{GN}), and (e) heat dissipation rate.

Corresponding reference characters indicate corresponding elements among the view of the drawings. The headings used in the figures do not limit the scope of the claims.

### DETAILED DESCRIPTION

A system and associated methods for the assessment of Li-Ion battery thermo-electrochemical performance and battery thermal management requirements are disclosed herein. The methods introduce new parameters that may better characterize thermo-electrochemical performance of Li-Ion batteries and associated thermal management systems.

There exists a need for battery thermal performance assessment independent of design forms, geometries, and capacities. Previously outlined temperature related metrics such as maximum temperature and maximum temperature difference depend on ambient temperature and cell geometry and characteristics. Moreover, heat related metrics such as the cell cooling coefficient (CCC) and the CCC for geometry and heat normalization depend on cell capacity and are not generalized in definition because of their dependence on certain cell characteristics at 50% state of charge only.

Therefore, absolute metrics are outlined for the selection of proper battery thermal management systems (BTMSs) and normalized metrics are outlined for battery thermal performance evaluation.

A new approach utilizes new parameters for battery thermo-electrochemical performance evaluation and battery thermal management system requirements assessment. The approach utilizes cell hybrid pulse power characteristics (HPPC) with continuous discharge tests at different temperatures in cells beginning of life. The new approach may be leveraged in battery specification sheets as a general comparison tool against other cells of different capacities, energy/power densities, design forms, and dimensions.

Cell thermo-electrochemical performance can be assessed using the normalized heat generation ratio (NHGR) to determine the ratio of waste to stored energy independent of all cell characteristics. Furthermore, cell thermal performance is assessed using cell thermal efficiency to identify the cell capability to efficiently dissipate the generated heat during operation with ideal prescribed objectives at total surface cooling (ηₜₕ) and ideal design point (η_{th-IDP}).

Moreover, the thermal efficiency ratio (α) of both described thermal efficiencies is a great tool to define the required heat dissipation compared to the maximum reachable heat dissipation. For BTMS requirements, heat dissipation required for ideal prescribed objectives is estimated as an absolute metric for BTMS selection.

A demonstration of the outlined methodology using outlined metrics is performed on the INR21700-50E and NCR18650PF cells. An experimental study was conducted to obtain cells characteristics. Afterwards, Numerical models were applied to define and explore the outlined metrics for all BTMS design points.

As for thermal performance assessment, the INR21700-50E cell is worse in the thermo-electrochemical behavior represented by a 20.66% higher NHGR due to its higher capacity by 69.97% compared to the NCR18650PF cell. The INR21700-50E cell thermal behavior, on the other hand, outperforms with lower ideal design point thermal efficiency (η_{th-IDP}) by 8.5% with a BTMS requirement of 0.829 W.

Finally, the outlined metrics are recommended to be reported as thermal behavior information in cell manufacturer sheets.

### 1. Introduction

Recent cell thermal performance metrics for BTMSs could be classified into temperature-based and heat rate-based parameters. The temperature-based parameters target the definition of temperature extremes and distribution across cells such as the average temperature (T_{avg}), maximum temperature (Tₘₐₓ), maximum temperature difference (ΔTₘₐₓ), temperature uniformity, and temperature standard deviation. Other recently outlined parameters are those related to heat rate such as the cell cooling coefficient (CCC) (W/K) defined as the ratio of heat rate dissipated (Q_{diss}) (W) to the maximum temperature difference (K). For CCC capacity normalization, the per capacity coefficient (PCC) (W/K·Ah) is defined as the ratio of the CCC to the beginning of life capacity (BoL capacity) (Ah). The PCC is also a normalization of the number of layers because of the direct relation between layers number and the cell capacity. Furthermore, the cell cooling coefficient for geometry normalizations to aspect ratios (CCC_{GN-AR}) is defined by dividing the CCC by the heat transfer area (A) divided by the heat transfer length (L) for a normalization to the cell aspect ratio. Another heat rate related parameter for modules is the module cooling coefficient (MCC). The MCC is computed by dividing the heat dissipated by the cooled region average temperature reduction between a BTMS and passive air cooling. Moreover, cooling energy efficiency coefficient (8) which could be defined like the coefficient of performance (COP) by dividing the heat dissipated by the power required for BTMSs.

### 2. Li-Ion Battery Thermal Performance Metrics

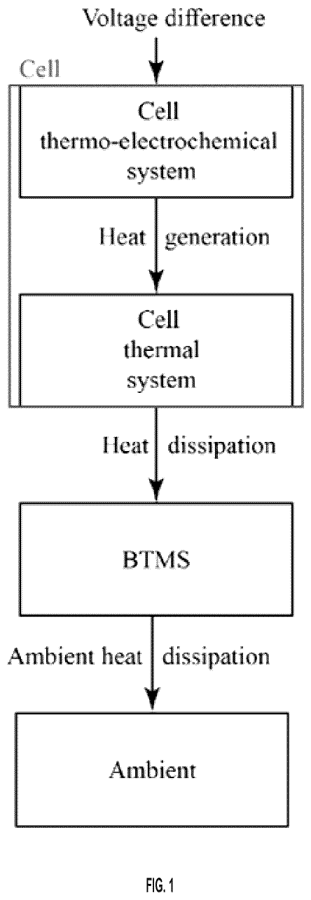

To effectively study a cell, interactions between chemical, electrical, and thermal behavior are divided into subsystems as demonstrated in FIG. 1. The thermo-electrochemical subsystem represents the conversion of stored energy to electrical energy and heat generation. The thermo-electrochemical subsystem treats the cell material as an active material with the trigger of a voltage difference applied as a driving force. Better thermo-electrochemical systems are recognized for higher percentages of electrical energy converted from stored energy. Afterwards, the cell thermal system represents cells as systems receiving the heat generated which is partially stored within the cell or dissipated towards the BTMS. Better cell thermal performance is recognized with higher heat dissipation. Despite the two cell subsystems are interactive, their separation is for clearly defined metrics for each system. Finally, the BTMS receives heat dissipation as an input which is partially removed towards the ambient as ambient heat dissipation.

Battery thermal performance is crucial because of the direct effects on short-term characteristics like discharge power and energy and long-term features like degradation. Therefore, different assessment metrics should be identified to successfully estimate cell thermo-electrothermal system performance. The comparison between the average heat rate generated and the average stored power available estimates electrical power and energy generated during discharge.

The average heat rate produced is calculated using the ECM average series resistance (Rₛ) estimated by the HPPC tests. The estimation of the heat generation and dissipation rates at 50% SoC, as previously outlined, is not quite accurate because the extremes of SoC working ranges have tremendous increases in terminal resistances for numerous cells. Therefore, all the outlined parameters are averaged through the entire cell working range. Afterwards, an average value of the open circuit voltage across the working SoC range is also estimated. Finally, the ratio of the heat rate generated to the available electrical power (P_{elec}) is defined as the heat generation ratio (HGR) as calculated in the following equation, which gives a crucial estimation of discharge efficiency considering the C-rate intensity.

$$HGR = \frac{{Q}_{gen}}{{P}_{elec}} = \frac{{I}^{2} {R}_{0}}{{IV}_{OC}} = \frac{{IR}_{0}}{{V}_{OC}}$$

The HGR could be calculated using 1 C-rate which broadens its usage as a cell discharge comparison metric for different cells. Moreover, cell electrical efficiency based on heat generation could be calculated by dividing the heat generation by the total power available (Pₜₒₜ) as follows.

$${η}_{e l e c} = \frac{{P}_{e l e c}}{{P}_{tot}} = \frac{{P}_{e l e c}}{{Q}_{g e n} + {P}_{e l e c}} = \frac{{IV}_{OC}}{{I}^{2} {R}_{0} + {IV}_{OC}} = \frac{{V}_{OC}}{{IR}_{0} + {V}_{OC}}$$

Furthermore, to normalize the effect of capacity differences between cells, an independence on current should be imposed. Therefore, the normalized heat generation ratio (NHGR) (A⁻¹) is outlined to evaluate the heat generation normalized to cell capacities through the division by current as calculated in the following equation.

$$N H G R = \frac{H G R}{I} = \frac{{R}_{0}}{{V}_{OC}}$$

For the cell thermal system performance assessment, if the average of heat rate dissipated is divided by the average of maximum temperature difference, this gives rise to a new definition of the CCC (W/K) which resembles the reciprocal of the spatial thermal resistance. The new definition is like a previous definition (i.e., previous definition being

$$CCC = \frac{{Q}_{diss}}{Δ {T}_{max}}$$

discussed herein as Eq. 2). However, this new definition of independent parameters makes the process of evaluating the CCC significantly easier than the previously outlined metric which required square charging and discharging pulses at 50% SoC for approximately 6 hours. Therefore, the CCC (W/K) is defined based on total surface area cooling through 1 C continuous discharge from 100% to 5% SoC to assess the integration of the total heat generation and dissipation through the entire working range and not for the 50% SoC only. For geometry normalization, the CCC_{GN} (W/m2·K) is defined as the ratio of the CCC by the cell heat transfer area, which is similar to the well-known overall heat transfer coefficient.

$${CCC}_{GN} = \frac{CCC}{A}$$

This metric is different from the geometry normalized CCC previously outlined which multiplies the currently outlined definition by the cooling length. However, the previous metric targets the comparison of different cell aspect ratios which unfortunately led to a departure from the main heat transfer definitions unlike the outlined metric.

The cell thermal efficiency (ηₜₕ) is calculated by dividing the actual heat dissipated by the maximum heat dissipated which equals the heat generated. Therefore, ηₜₕ could be used as a cell thermal efficiency comparison metric.

$${η}_{th} = \frac{{Q}_{diss}}{{Q}_{gen}}$$

The outlined thermal efficiency is extremely useful to compare different cells of different capacities unlike the previously outlined metric, CCC_{HN}, which depends on cell capacities. Because ηₜₕ depends on the ratio of the heat dissipation and heat generation for the same cell at the same current intensity, the dependence on different cells current intensities at the same C-rate (1 C for the outlined metric) is normalized and eliminated. Therefore, cells of different capacities could be efficiently compared in terms of thermal performance using the outlined thermal efficiency normalized metric. Consequently, Higher values of ηₜₕ represent better cell thermal performance with ideal ηₜₕ equals to unity.

### 3. BTMS Selection Metrics

Appropriate thermal system selection is a decisive decision leading to desirable specific cell thermoelectrical operating conditions. Furthermore, the available heat dissipation rates are also defined by the selected BTMS. Consequently, the power input to the BTMS consumed from the battery capacity directly affects the overall system performance. Hence, for proper thermal system selection, three values should be identified:

The thermal system heat transfer area.

The heat dissipation flux required per unit maximum surface temperature difference is identified through the CCC_{GN} which is like the overall heat transfer coefficient.

The required heat dissipation rate for a predefined maximum temperature difference across the cell surface is defined by the CCC to assess the heat dissipation rate required.

To investigate the outlined methodology of thermal system selection, an ideal thermal objective needs to be identified as a test case. Therefore, an ideal design point (IDP) is outlined which has an ambient temperature of 25° C. as a standard ambient temperature. Moreover, a cooling temperature is higher than the ambient temperature by 3° C., for phase change temperatures (PCTs) consideration. Furthermore, a maximum temperature difference of 3° C. is chosen as recommended for low voltage unbalance regarding cell level. After applying the previous considerations, the maximum cell temperature equals 31° C. The purpose of this ideal design point is to estimate the just adequate cooling area required at the IDP (A_{IDP}) which is determined using the response surface methodology as an ideal strict objective. Therefore, the IDP is used as a standard objective depending on standard conditions as design parameters to generalize its use for all cells and applications. Moreover, CCC_{IDP} and CCC_{GN-IDP} could also be calculated to estimate the required heat rate and heat flux for the IDP.

To establish other cell thermal performance assessment indicators, the IDP is compared to the ideal case to assess the IDP requirements availability depending on the cell thermal design. The IDP aims for a partial cooling of the cell surface for lower BTMS requirements as will be discussed thoroughly in the section 6.3.2 below. Therefore, an area ratio (σ) discovers the availability of the required heat transfer area by comparing the A_{IDP} to the total cell surface area as calculated in the following equation. Despite the important σ definition, the heat transfer area is still the main comparison metric for different cells comparison because of the heat transfer concepts.

$$σ = \frac{{A}_{IDP}}{A} = \frac{{l}_{IDP}}{l}$$

Another comparison tool is established by dividing heat dissipation rate for the IDP (Q_{diss-IDP}) by the average heat rate generation to find the IDP thermal efficiency required (η_{th-IDP}). This indicates just adequate heat dissipation to make the cell at the IDP with minimum cooling power and energy. Unlike ηₜₕ, lower values of η_{th-IDP} indicate better cell thermal performance because it means that lower thermal efficiency is adequate to achieve the IDP requirements as calculated as follows.

$${η}_{th - IDP} = \frac{{Q}_{diss - IDP}}{{Q}_{gen}}$$

Furthermore, the thermal efficiency ratio (α) is defined as the ratio of the η_{th-IDP} to ηₜₕ. α is for the estimation of the IDP thermal efficiency compared to the total surface cooling case by using Q_{diss} at the total surface cooling case and not for the ideal, not existing, case as in η_{th-IDP} by using Q_{gen}. However, η_{th-IDP} is outlined to estimate the thermal efficiency compared to the cell ideal requirements as calculated as follows.

$$α = \frac{{η}_{th - IDP}}{{η}_{th}} = \frac{{Q}_{diss - IDP}}{{Q}_{diss}}$$

To summarize, A_{IDP}, CCC_{IDP}, and CCC_{GN-IDP} are the output of an efficient thermal system selection procedure. Using the IDP as a general ideal objective, the IDP thermal requirements could be compared to the ideal case to discover cell thermal design efficiency. Consequently, σ and η_{th-IDP} are utilized as other outlined cell thermal performance assessment metrics and to compare the IDP to the idealized cell case. Whereas a is used to compare the IDP to a real predefined case. Therefore, BTMS absolute requirements could be identified using the heat dissipation required at the IDP. This parameter achieves the ideal objective and represents the required heat dissipation as a performance parameter of the BTMS regardless of its type.

A novel data-driven model for battery thermo-electrochemical performance assessment and battery thermal management system requirements evaluation. Section 6 outlines further details of the systems and methods, and is incorporated by reference in its entirety. The model depends on hybrid pulse power characteristics (HPPC) and continuous discharge tests at only the beginning of life of one cell. Depending on the novel approach parameters, battery performance could be clearly assessed and compared to batteries of different capacities, design forms, dimensions, and chemistries. Therefore, successful battery selection and control optimization could be achieved with high reliability resulting in overall battery cost reduction. Moreover, battery manufacturing parameters could be integrated with the outlined methodology for optimized overall thermo-electrochemical performance. The model resulted in successful performance assessment and comparison depending on novel parameters other than conventional independent parameters such as energy/power density, maximum temperature and maximum temperature difference. Table 1 represents a successful comparison of two cells.

TABLE 1
Summary of Metrics of Two Cells

| | |
|---|---|
| NCR18650PF | INR21700-50E |

General Inf.

| | | |
|---|---|---|
| D(m) | 0.018 | 0.021 |
| L(m) | 0.065 | 0.070 |
| Capacity (Ah) | 2.900 | 4.900 |
| R₀₋ₐᵥₑ (Ω) | 0.032 | 0.039 |
| V_{OC-ave} (V) | 3.709 | 3.746 |
| A (m²) | 3.68E−03 | 4.67E−03 |
| Q_{gen} (W) | 0.272 | 0.945 |
| HGR | 0.025 | 0.051 |
| η_{elec} | 0.975 | 0.951 |
| NHGR (A⁻¹) | 0.009 | 0.011 |

Total surface cooling case

| | | |
|---|---|---|
| ΔTₘₐₓ (K) | 1.174 | 0.983 |
| Q_{diss} (W) | 0.264 | 0.909 |
| CCC (W/K) | 0.225 | 0.925 |
| CCC_{GN} (W/m²) | 61.315 | 197.863 |
| ηₜₕ | 0.973 | 0.962 |

IDP case

| | | |
|---|---|---|
| l (m) | 0.047 | 0.025 |
| A_{IDP} (m²) | 2.65E−03 | 1.68E−03 |
| σ_{IDP} | 0.721 | 0.360 |
| ΔTₘₐₓ (K) | 1.403 | 1.744 |
| Q_{diss-IDP} (W) | 0.261 | 0.829 |
| CCC_{IDP} (W/K) | 0.186 | 0.476 |
| CCC_{GN-IDP} (W/m² · K) | 70.105 | 282.469 |
| η_{th-IDP} | 0.959 | 0.877 |
| α | 0.985 | 0.912 |

The functions performed in the processes and methods may be implemented in differing order. Furthermore, the outlined steps and operations are provided as examples, and some of the steps and operations may be optional, combined into fewer steps and operations, or expanded into additional steps and operations without detracting from the essence of the disclosed embodiments.

### 4. System Architecture

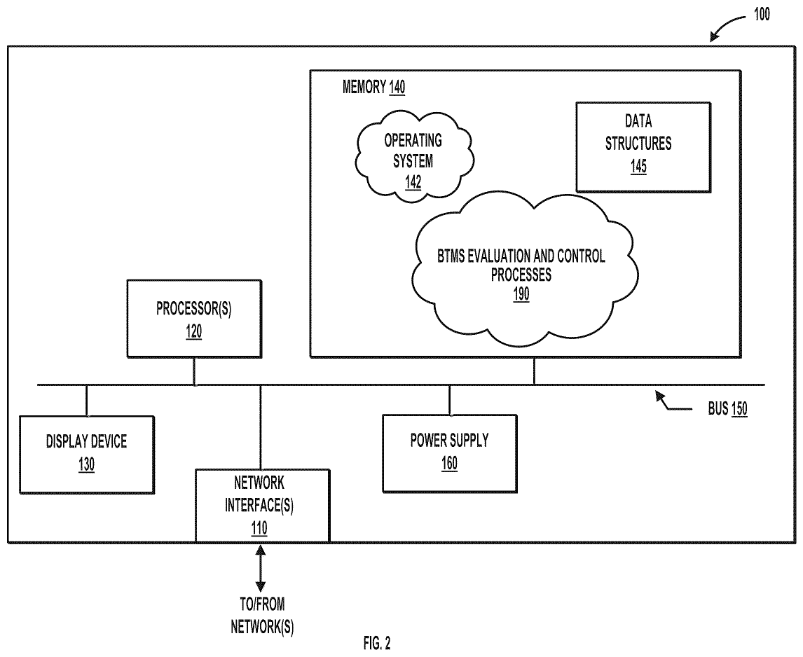

FIG. 2 is a schematic block diagram of an example device 100 that may be used with one or more embodiments described herein, e.g., as a component of the system and implementing methods outlined herein.

Device 100 comprises one or more network interfaces 110 (e.g., wired, wireless, PLC, etc.), at least one processor 120, and a memory 140 interconnected by a system bus 150, as well as a power supply 160 (e.g., battery, plug-in, etc.). Device 100 can also include or otherwise communicate with a display interface device 130 which can include one or more input/output devices that enable a user to input data, and to view or otherwise access output data. Input/output devices can include but are not limited to a monitor, a touch-screen, a speaker, a keyboard, a mouse, and the like.

Network interface(s) 110 include the mechanical, electrical, and signaling circuitry for communicating data over the communication links coupled to a communication network. Network interfaces 110 are configured to transmit and/or receive data using a variety of different communication protocols. As illustrated, the box representing network interfaces 110 is shown for simplicity, and it is appreciated that such interfaces may represent different types of network connections such as wireless and wired (physical) connections. Network interfaces 110 are shown separately from power supply 160, however it is appreciated that the interfaces that support PLC protocols may communicate through power supply 160 and/or may be an integral component coupled to power supply 160.

Memory 140 includes a plurality of storage locations that are addressable by processor 120 and network interfaces 110 for storing software programs and data structures associated with the embodiments described herein. In some embodiments, device 100 may have limited memory or no memory (e.g., no memory for storage other than for programs/processes operating on the device and associated caches). Memory 140 can include instructions executable by the processor 120 that, when executed by the processor 120, cause the processor 120 to implement aspects of the systems and the methods outlined herein.

Processor 120 comprises hardware elements or logic adapted to execute the software programs (e.g., instructions) and manipulate data structures 145. An operating system 142, portions of which are typically resident in memory 140 and executed by the processor, functionally organizes device 100 by, inter alia, invoking operations in support of software processes and/or services executing on the device. These software processes and/or services may include BTMS evaluation and control processes 190, which can include aspects of the methods and/or implementations of various modules described herein. Note that while BTMS evaluation and control processes 190 is illustrated in centralized memory 140, alternative embodiments provide for the process to be operated within the network interfaces 110, such as a component of a MAC layer, and/or as part of a distributed computing network environment.

It will be apparent to those skilled in the art that other processor and memory types, including various computer-readable media, may be used to store and execute program instructions pertaining to the techniques described herein. Also, while the description illustrates various processes, it is expressly contemplated that various processes may be embodied as modules or engines configured to operate in accordance with the techniques herein (e.g., according to the functionality of a similar process). In this context, the term module and engine may be interchangeable. In general, the term module or engine refers to model or an organization of interrelated software components/functions. Further, while the BTMS evaluation and control processes 190 is shown as a standalone process, those skilled in the art will appreciate that this process may be executed as a routine or module within other processes.

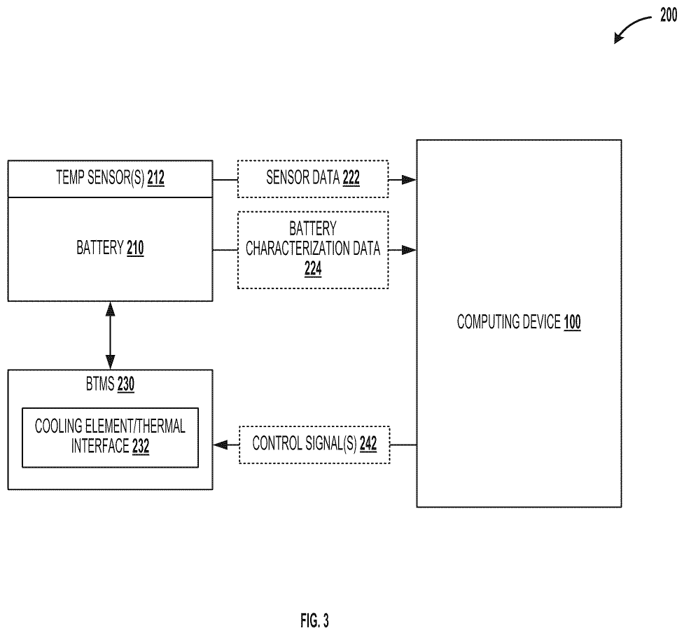

FIG. 3 illustrates an example system 200 that includes computing device 100 in communication with a battery 210 and a battery thermal management system (BTMS) 230. The battery 210 includes one or more temperature sensors 212. The temperature sensor(s) 212 provide sensor data 222 to the computing device 100. In some embodiments, the sensor data 222 includes measured temperature data measured at a surface of the battery 210, and the measured temperature data may include one or more time series of temperature measurements and/or one or more filtered or aggregated temperature values derived from the temperature measurements.

The computing device 100 further retrieves, measures, or otherwise accesses battery characterization data 224 associated with the battery 210. In some embodiments, the battery characterization data 224 includes hybrid pulse power characterization (HPPC) data and continuous discharge data collected during test operation of the battery 210. As described herein, the computing device 100 executes instructions stored in memory to construct an equivalent circuit model (ECM) of the battery 210 using the battery characterization data 224, generate thermal response values across combinations of BTMS parameter values, generate a mapping relating BTMS parameters to thermal response quantities, transform prescribed thermal limit data into one or more target BTMS settings, and generate one or more control signal(s) 242 for operating the BTMS 230.

The BTMS 230 includes a cooling element and/or thermal interface 232 configured to remove heat from the battery 210. The computing device 100 outputs one or more control signal(s) 242 to the BTMS 230 to set one or more BTMS operating parameters, thereby establishing a cooling boundary condition at the battery 210 and maintaining the battery 210 within prescribed thermal limits during discharge. In some embodiments, the one or more BTMS operating parameters include at least a cooling temperature setpoint and a cooled-surface cooling length (e.g., a cooling coverage length or cooled-region extent along a surface of the battery 210).

### 5. Computer-Implemented Method

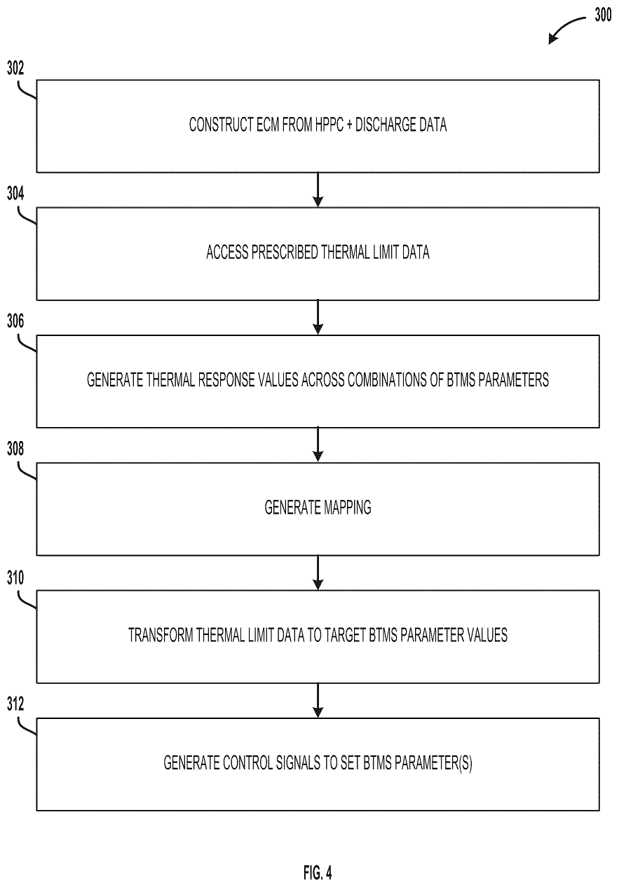

FIG. 4 illustrates an example computer-implemented method 300 for determining target BTMS parameter values and generating control signals for operating a BTMS. In the illustrated embodiment, the method 300 includes constructing an equivalent circuit model (ECM) from HPPC data and discharge data (step 302). The method 300 further includes accessing prescribed thermal limit data (step 304), where the prescribed thermal limit data includes one or more threshold values for battery thermal behavior during discharge with respect to cooling by a BTMS.

The method 300 further includes generating thermal response values across combinations of BTMS parameters (step 306). In some embodiments, the BTMS parameters include a cooling temperature setpoint and a cooled-surface cooling length. The method 300 includes generating a mapping (step 308) that relates the BTMS parameters to at least a battery surface maximum temperature and a battery surface temperature difference. The method 300 further includes transforming the thermal limit data to one or more target BTMS parameter values (step 310). The method 300 further includes generating control signals to set one or more BTMS parameter(s) (step 312), thereby causing the BTMS to operate in accordance with the target BTMS parameter value(s) and maintain the battery within the prescribed thermal limit data.

As discussed, the method includes constructing (e.g., by a processor of a computing system executing instructions stored in a memory and in communication with a battery system) an equivalent circuit model (ECM) of the battery using battery characterization data collected during test operation of the battery. As used herein, “battery characterization data” includes hybrid pulse power characterization (HPPC) data and continuous discharge data. In some embodiments, the ECM comprises a two-RC-branch ECM (2RC ECM) parameterized by an open-circuit voltage V_{OC} and electrical elements including a series resistance and two RC polarization branches, for example using parameters Rₛ, R₁, C₁, R₂, and C₂. The method may include determining one or more ECM parameters by fitting the ECM to the HPPC data and the continuous discharge data.

In some embodiments, the ECM provides predicted electrical response quantities that are used as inputs to thermal modeling during discharge. For example, a terminal voltage Vt may be expressed in terms of V_{OC}, a current I, and one or more polarization voltages (e.g., V₁, V₂). In some embodiments, one or more ECM parameters are treated as functions of operating conditions such as temperature and state of charge, and the ECM is validated by comparing predicted voltage response to measured voltage response for one or more discharge profiles.

The method may further include computing one or more electrical and electro-thermal quantities from the equivalent circuit model during discharge. For example, the method may include computing electrical power delivered by the battery, denoted P_{elec}, and total electrical power, denoted Pₜₒₜ, based on the model current I and model voltages (e.g., Vt and/or V_{OC}). The method may also include computing a heat generation rate, denoted Q_{gen}, based on the equivalent circuit model parameters and discharge conditions, such as internal resistance and current (e.g., using model current I, a resistance term R₀ or Rₛ, and V_{OC}). In some embodiments, R₀ denotes an internal resistance value derived from the ECM parameterization (e.g., a DC or series resistance associated with the ECM), and the method may treat R₀ and/or V_{OC} as functions of temperature and state of charge.

The method may further include computing an electrical efficiency η_{elec} and one or more heat-generation ratios. For example, the method may include computing η_{elec} using P_{elec}, Pₜₒₜ, and Q_{gen} and computing a heat generation ratio HGR using Q_{gen} and P_{elec}. The method may also include computing a normalized heat generation ratio NHGR as a function of HGR and I, and in some embodiments NHGR is expressed in terms of R₀ and V_{OC}. These quantities may be stored as additional model outputs and may be used to characterize the battery and/or to compare operating conditions.

The method includes accessing (e.g., by the processor) prescribed thermal limit data for the battery during discharge with respect to cooling by a battery thermal management system (BTMS). As used herein, “prescribed thermal limit data” includes at least (i) a maximum allowable battery surface temperature and (ii) a maximum allowable temperature difference across a battery surface of the battery. These quantities correspond to thermal response/performance parameters used throughout this disclosure, including a maximum battery surface temperature Tₘₐₓ and a maximum battery surface temperature difference ΔTₘₐₓ.

In some embodiments, the prescribed thermal limit data is provided as a data structure stored in the memory and accessed by the processor, and may include one or more numeric thresholds, one or more threshold profiles, and/or one or more threshold values that depend on operating condition. For example, the prescribed thermal limit data may include a threshold for maximum surface temperature and a threshold for maximum surface temperature difference to be satisfied during discharge under one or more discharge conditions.

The method includes generating (e.g., by the processor) thermal response values for each of a plurality of combinations of BTMS parameters that include (i) a cooling temperature setpoint and (ii) a cooled-surface cooling length of the battery. As used herein, the “cooling temperature setpoint” corresponds to an imposed constant temperature value for a cooled portion of the battery surface and may be denoted T_{cool}. As used herein, the “cooled-surface cooling length” corresponds to an extent of the cooled portion of the battery surface and may be denoted l. For convenience, the BTMS parameters may be represented as a parameter vector p=[T_{cool}, l], though other representations may be used.

The method includes generating the thermal response values using the ECM together with a cooling boundary condition target defined by the BTMS parameters. In some embodiments, the cooling boundary condition target comprises a constant-temperature boundary condition applied to a cooling region (or cooled portion) of the battery surface. For example, the method includes applying a boundary condition that maintains the cooled portion of the battery surface at a temperature equal to T_{cool} over a surface region whose extent corresponds to the cooled-surface cooling length l. In some embodiments, the cooled portion is positioned as a centered portion of the battery surface.

The method includes generating (e.g., by the processor) a mapping from thermal response values generated using the ECM. As used herein, the “mapping” includes one or more functional relationships that relate the BTMS parameters p (e.g., T_{cool} and l) to thermal performance parameters including at least Tₘₐₓ and ΔTₘₐₓ. In some embodiments, the mapping comprises one or more response surfaces or surrogate models, for example Tₘₐₓ=ƒ₁(p) and ΔTₘₐₓ=ƒ₂(p), though other model forms may be used.

In some embodiments, the thermal response values used to generate the mapping further include one or more heat-transfer-related quantities. For example, the thermal response values may include a heat dissipation rate Q_{diss} and/or one or more coefficients derived from Q_{diss}, such that the mapping relates the BTMS parameters to Q_{diss} and/or such derived coefficients in addition to Tₘₐₓ and ΔTₘₐₓ.

In some embodiments, the method includes selecting the plurality of combinations of BTMS parameters using a design-of-experiments approach. For example, the method includes selecting combinations of T_{cool} and l using a central composite design, and in some embodiments a face-centered central composite design. In some embodiments, this selection approach provides coverage of a BTMS parameter space while reducing the number of combinations evaluated relative to a brute-force grid.

In some embodiments, the method includes refining the mapping by selecting one or more refinement combinations of the BTMS parameters and generating additional thermal response values for those refinement combinations. Predicted values produced by the mapping at a candidate refinement combination may be compared to calculated values represented by the additional thermal response values. In some embodiments, the method includes reducing an error between predicted values and calculated values using a Kriging algorithm, thereby improving the mapping accuracy over the BTMS parameter space.

In addition to temperature-related thermal response values (e.g., Tₘₐₓ and ΔTₘₐₓ, the method may include computing heat-removal and cooling-coefficient quantities for each evaluated combination of BTMS parameters. For example, the method may include computing a heat dissipation rate Q_{diss} that represents heat removed from the battery under the cooling boundary condition target. In some embodiments, the method uses a sign convention in which Q_{diss} is negative when heat leaves the battery; as used herein, “heat dissipation rate” may refer to the signed quantity Q_{diss} or to a corresponding magnitude |Q_{diss}| depending on context, including when identifying required BTMS heat removal.

The method may further include computing a cooling coefficient, denoted CCC, based on Q_{diss} and a temperature difference associated with the cooling boundary condition target (e.g., a difference between a representative battery temperature and the cooling temperature setpoint). The method may also include computing a geometry-normalized cooling coefficient, denoted CCC_{GN}, based on CCC and a heat transfer area A. In some embodiments, the mapping generated by the method relates the BTMS parameters to Q_{diss}, CCC, and/or CCC_{GN} in addition to relating the BTMS parameters to Tₘₐₓ and ΔTₘₐₓ.

The method includes transforming (e.g., by the processor) the prescribed thermal limit data, based on the mapping, into at least one target BTMS parameter value for at least one BTMS parameter of the BTMS. For example, given a maximum allowable battery surface temperature T_{max,lim} and (ii) a maximum allowable temperature difference across a battery surface of the battery ΔT_{max,lim} and the mapping ƒ(p), the method includes selecting a target parameter vector p* such that predicted thermal performance satisfies the prescribed thermal limit data, e.g., ƒ₁(p*)≤T_{max,lim} and ƒ₂(p*)≤ΔT_{max,lim}. The target BTMS parameter value(s) may include, for example, a target cooling temperature setpoint

$${T}_{cool}^{*}$$

and/or a target cooled-surface cooling length l*.

In some embodiments, the method includes selecting the target BTMS parameter value(s) by optimizing one or more objectives subject to the prescribed thermal limit data. For example, the method includes selecting p* to satisfy the thresholds while minimizing cooling intensity and/or minimizing a cooled-surface extent. Other objectives may be used.

In some embodiments, the method includes identifying an ideal design point (IDP) in a BTMS parameter space, where the IDP corresponds to a combination of BTMS parameters that satisfies prescribed thermal limit data under discharge while representing an “idealized” constant-temperature cooling condition over a cooling region. The method may represent the cooling-region size using a cooled-surface length I and/or a cooling heat transfer area A. In such embodiments, an “IDP cooling area” A_{IDP} represents a cooling area that is sufficient (and, in some embodiments, just sufficient) to satisfy the prescribed thermal limit data under the IDP condition, and the method may compute or select A_{IDP} based on the mapping and/or the thermal response values. Where an area ratio is used, the method may define a dimensionless area ratio (e.g., A_{IDP}/A) to express a relative cooling-region extent.

The method may further include computing an IDP heat dissipation quantity Q_{diss-IDP} that represents a heat dissipation rate associated with the IDP. In some embodiments, the “required heat dissipation rate” recited in the method corresponds to Q_{diss-IDP}, and the method includes selecting at least one target BTMS parameter value based on Q_{diss-IDP} in addition to selecting target BTMS parameter values based on temperature-related limits (e.g., thresholds related to Tₘₐₓ and ΔTₘₐₓ). Stated differently, the method may use the mapping to transform prescribed thermal limit data into (i) target BTMS parameter values and (ii) a corresponding BTMS heat-removal requirement represented by Q_{diss-IDP}.

The method includes generating (e.g., by the processor) one or more control signals using measured temperature data measured at the battery surface. As used herein, measured battery surface temperature data corresponds to temperature measurements acquired during battery operation. The method further includes outputting control signals (e.g., control commands u (t)) that set the at least one BTMS parameter to the at least one target BTMS parameter value, thereby causing the BTMS to operate in accordance with the selected target parameter values and to establish the cooling boundary condition target at the battery surface.

In some embodiments, the method includes transforming the prescribed thermal limit data, based on the mapping and the thermal response values, into a required heat dissipation rate to be provided by the BTMS. As used herein, “required heat dissipation rate” corresponds to a heat dissipation quantity denoted Q_{diss-IDP} in an ideal design point (IDP) context, representing a heat dissipation rate required by the BTMS consistent with the prescribed thermal limit data. More generally, heat dissipation rate values may be denoted Q_{diss}. In some embodiments, the target BTMS parameter value(s) are selected based on the required heat dissipation rate Q_{diss-IDP}, such that the selected target parameter values correspond to provision of at least the required heat dissipation rate.

The method may further include computing one or more thermal efficiency quantities based on heat generation and heat dissipation. For example, the method may include computing a thermal efficiency ηₜₕ as a ratio of heat dissipation to heat generation, such as ηₜₕ=Q_{diss}/Q_{gen} under a given evaluated combination of BTMS parameters. The method may also include computing an IDP thermal efficiency η_{th-IDP} based on Q_{diss-IDP} and Q_{gen}, and computing a comparison ratio α based on η_{th-IDP} and ηₜₕ h (and/or based on Q_{diss-IDP} and Q_{diss}). These quantities may be reported as additional outputs for comparing cooling configurations and/or for selecting or ranking candidate BTMS parameter values, while the target BTMS parameter values themselves may be selected to satisfy the prescribed thermal limit data.

In some embodiments, the method includes computing “real” BTMS performance quantities during operation using measured temperature data. For example, the method may include computing an average heat dissipated through a BTMS, denoted Q_{diss-real}, and computing a real thermal efficiency ηₜₕ₋ᵣₑₐₗ based on Q_{diss-real} and a stored heat quantity Q_{cell-stored} represented by an average cell temperature. In some embodiments, the method includes estimating an average cell temperature using a model that relates measured battery surface temperature(s) to average cell temperature, and using the estimated average cell temperature to compute Q_{cell-stored}. These quantities may be reported and/or used to evaluate BTMS operation, including comparisons between an IDP-based required heat dissipation quantity and measured BTMS heat dissipation during operation. In some embodiments, a trained model relates surface temperature measurements to an average cell temperature to support estimation of such “real” quantities.

In embodiments, the required heat-removal setpoint is provided to a BTMS controller that translates the setpoint into actuator commands based on the BTMS architecture and available actuators (e.g., pump, fan, valve, compressor, or thermoelectric device). The translation may be implemented using a rule set, a feedback controller, a feedforward controller, model predictive control, or combinations thereof, and uses one or more measured temperatures associated with the battery to regulate heat removal such that prescribed thermal constraints are satisfied.

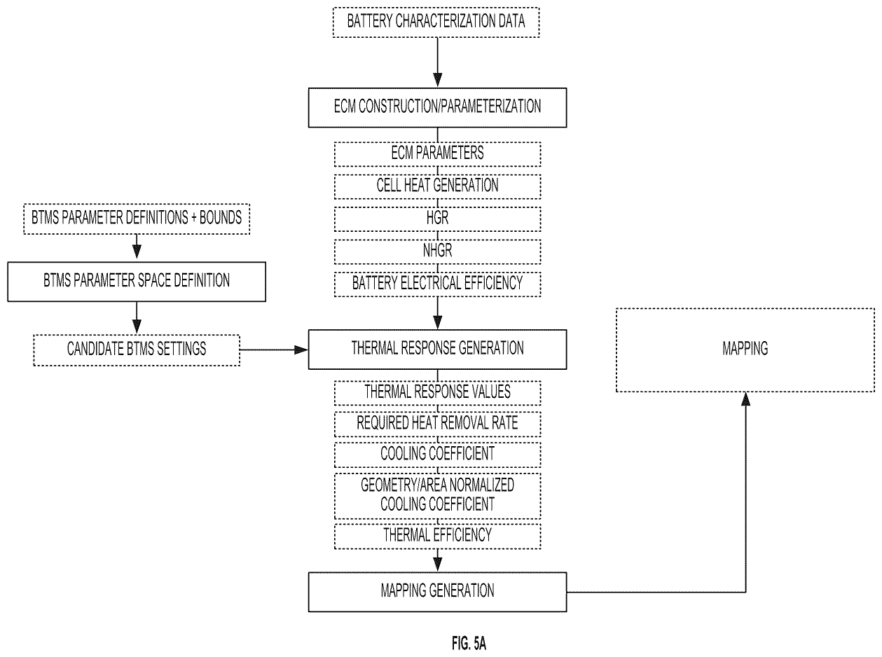

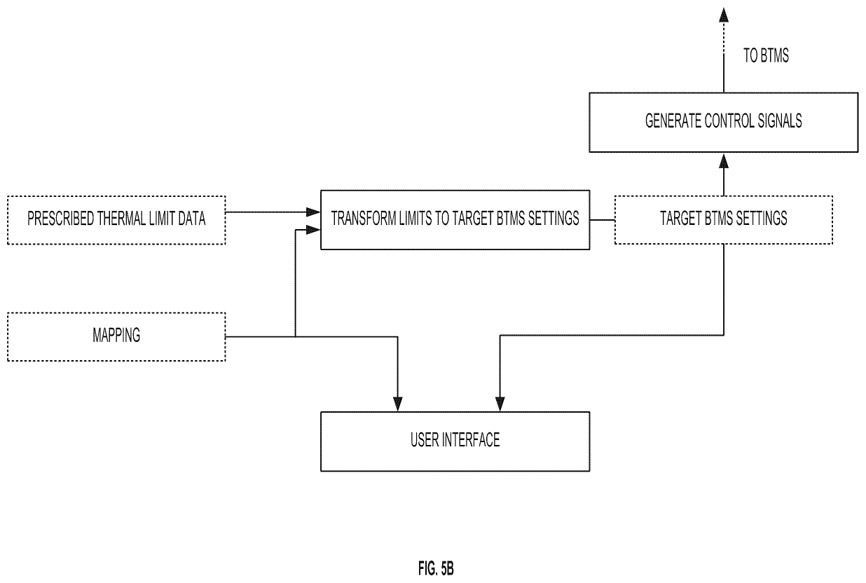

FIG. 5A illustrates an example data flow for generating a mapping that relates BTMS parameter values to thermal response behavior of a battery. The data flow includes receiving or accessing battery characterization data and performing ECM construction/parameterization. In some embodiments, ECM construction/parameterization yields ECM parameters and one or more model-derived electrical or electro-thermal quantities. For example, the illustrated embodiment depicts generation of cell heat generation and one or more derived quantities including a heat generation ratio (HGR), a normalized heat generation ratio (NHGR), and battery electrical efficiency. These quantities may be stored, output, and/or used as intermediate values for subsequent computations described herein.

The data flow further includes receiving or accessing BTMS parameter definitions and bounds and performing BTMS parameter space definition to produce candidate BTMS settings. As used herein, “candidate BTMS settings” include candidate combinations of BTMS parameter values to be evaluated, including at least a cooling temperature setpoint and a cooled-surface cooling length. The data flow includes thermal response generation for the candidate BTMS settings using the ECM. In some embodiments, thermal response generation includes applying, for each candidate BTMS setting, a cooling boundary condition corresponding to the cooling temperature setpoint and the cooled-surface cooling length, and generating thermal response values for the battery under the cooling boundary condition.

In the illustrated embodiment, thermal response generation produces one or more outputs including thermal response values and one or more derived quantities for reporting and/or sizing of BTMS operation. For example, the illustrated embodiment depicts outputs including a required heat removal rate, a cooling coefficient, a geometry/area normalized cooling coefficient, and a thermal efficiency. The data flow further includes mapping generation using the outputs of the thermal response generation, thereby producing the mapping. In some embodiments, the mapping comprises one or more response surfaces or surrogate models that relate candidate BTMS settings to thermal response values and/or to one or more derived quantities.

FIG. 5B illustrates an example data flow for transforming prescribed thermal limit data, based on a mapping, into target BTMS settings and generating control signals for operating a BTMS. In the illustrated embodiment, prescribed thermal limit data and the mapping are provided as inputs to a transformation process that yields target BTMS settings. The target BTMS settings represent one or more selected BTMS parameter values (e.g., a selected cooling temperature setpoint and/or a selected cooled-surface cooling length) that are predicted, via the mapping, to satisfy the prescribed thermal limit data during discharge.

The data flow further includes generating control signals based on the target BTMS settings. The generated control signals are output to the BTMS to set one or more BTMS operating parameters and establish the cooling boundary condition at the battery surface. In some embodiments, the data flow further includes providing one or more outputs to a user interface. For example, the user interface may present (i) the target BTMS settings, (ii) predicted thermal response values corresponding to one or more candidate BTMS settings and/or corresponding to the target BTMS settings, and (iii) one or more derived quantities (e.g., a required heat removal rate, a cooling coefficient, a geometry/area normalized cooling coefficient, and/or a thermal efficiency) for reporting, evaluation, or export (e.g., as fields for inclusion in a report or specification sheet).

TABLE 2
Nomenclature

| | |
|---|---|
| Abbreviations | |
| BJDST | Beijing Dynamic Stress test |
| BMS | Battery management system |
| BoL | Beginning of life |
| BTMS | Battery thermal management |
| | system |
| CCC | Cell cooling coefficient |
| CFD | Computational fluid dynamics |
| COP | Coefficient of performance |
| DoE | Design of experiment |
| DST | Dynamic Stress Test |
| ECM | Electric circuit model |
| EIS | Electrochemical impedance |
| | spectroscopy |
| FUDS | Federal urban driving schedule |
| HGR | Heat generation ratio |
| HTC | Heat transfer coefficient |
| HPPC | Hybrid pulse power |
| | characteristic |
| IDP | Ideal design point |
| MCC | Module cooling coefficient |
| MOGA | Multi-objective genetic algorithm |
| NHGR | Normalized heat generation ratio |
| NRC | Number of RC branches |
| PCC | Per capacity coefficient |
| PCM | Phase change material |
| PCT | Phase change temperatures |
| PNGV | Partnership for a New |
| | Generation of Vehicles |
| RSM | Response surface methodology |
| SoC | State of charge |
| SoH | State of health |
| UDDS | Urban dynamometer driving |
| | schedule |
| Roman | |
| symbols | |
| A | Heat transfer area |
| C | Polarization capacitance |
| Cp | Heat capacity |
| I | Current |
| j | Current transfer rate |
| k | Thermal conductivity |
| L | Heat transfer length |
| P | Power |
| q | Heat transfer rate per unit |
| | volume |
| Q | Heat transfer rate |
| R | Resistance |
| t | Time |
| T | Temperature |
| V | Voltage |
| Greek | |
| symbols | |
| α | Cell thermal efficiency ratio |
| β | Cooling energy efficiency |
| | coefficient |
| A | Difference |
| η | Efficiency |
| p | Density |
| | Electric conductivity |
| σ | Area ratio |
| p | Phase potential |
| Subscripts | |
| − | Negative electrode |
| + | Positive electrode |
| abuse | Abuse operations |
| avg | Average |
| Ech | Electrochemical reactions |
| elec | Electrical |
| gen | Generation |
| GN | Geometry normalization |
| GN-AR | Geometry normalization to the |
| | aspect ratio |
| HN | Heat normalization |
| i | Counter |
| max | Maximum |
| oc | Open circuit |
| s | Series |
| short | Short circuits |
| t | Terminal |
| th | Thermal |
| tot | Total |

### 6. Model-Based Determination of BTMS Operating Requirements

Recent breakthroughs in electric battery technology have led to much higher energy density batteries. This enables using batteries in numerous research fields and commercial applications. Recently outlined batteries could successfully replace fuel-based motorized applications with an acceptable compromise between economic and energy considerations. Due to the severe climate change currently encountered decarbonization requirements have made the utilization of electric based motors a critical step in the journey towards a green energy economy. However, the increase in energy density raises the issue of increasing battery temperature beyond acceptable limits. The incidents related to battery overheating hinder widespread battery adoption. Therefore, battery management systems (BMSs) are vital elements in the control of chemical, electrical, and thermal battery behaviors to avoid abnormal operational conditions. Consequently, creating efficient battery behavior models and performance metrics are of utmost necessity for selecting and assessing the effectiveness of BMSs.

Battery models could be generally classified into four categories: empirical, electrochemical, equivalent circuit, and data-driven models. Firstly, electrochemical models identify internal microscale processes through complex partial differential equations such as pseudo-2D model and single particle model. Therefore, the electrochemical models have high accuracy and interpretation of battery chemistry. However, high computation costs limit their adoption in online applications.

Empirical models use simplified mathematical functions to correlate the terminal voltage with independent parameters like state of charge (SoC) and current. Examples of empirical models that properly identify battery nonlinear characteristics are enhanced self-correction model, Nernst model, Shepherd model, Unnewehr universal model, and zero state hysteresis model. Data-driven models, on the other hand, use the system historical data and statistics to build relations between input and output variables using advanced artificial intelligence and machine learning algorithms without physical modeling. Examples of data-driven models are support vector machine model, extreme learning machine model, and neural networks.

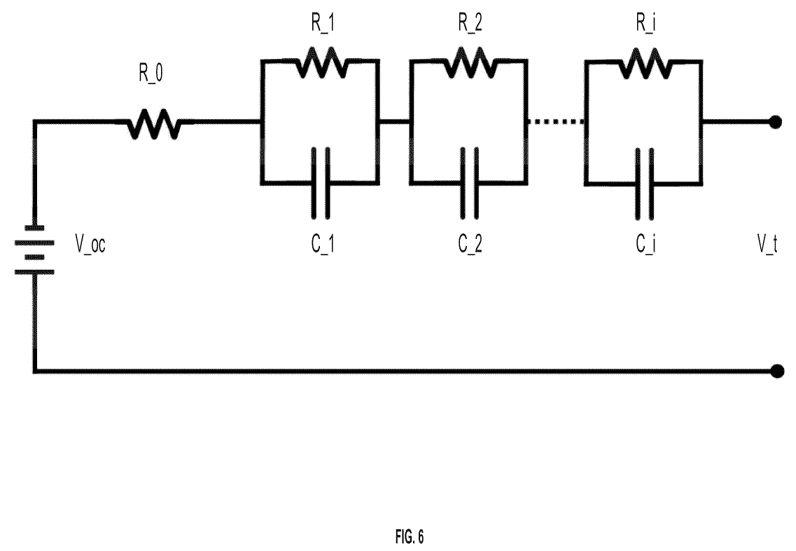

Electric circuit models (ECMs), on the other hand, use electric components as resistors and capacitors to capture the electrochemical behavior of batteries such as the Partnership for a New Generation of Vehicles (PNGV) model and number of RC branches (NRC) models. As shown in FIG. 6, NRC models contain numerous RC parallel components such as (ORC) Rint Model, (1RC) Thevenin model, (2RC) dual-polarization (DP) model, and the 3RC model. Although increasing the number of RC branches increases accuracy, the increased parameter identification difficulty and computational cost limit the usage of numerous branches. ECMs are widely used due to their advantages in accuracy, computation cost, and real-time estimation capability. Due to the ECMs advantages, integration of ECMs with BMSs is common and gives proper real-time simulation/feedback signals. The terminal voltage of the NRC ECM could be identified as follows.

$${V}_{t} = {V}_{OC} - {I}_{i} [ {R}_{s} + {\sum }_{i = 1}^{n} {R}_{i} ( 1 - {e}^{\frac{t}{{R}_{i} {C}_{i}}} ) ] \qquad ( 1 )$$

where Vt and V_{OC} are the terminal and open circuit voltages respectively. Whereas Rₛ and Rᵢ are the series and the i^{th} polarization resistances, respectively, and Cᵢ is the i^{th} polarization capacitance.

The ECM parameters could be identified by the hybrid pulse power characteristic (HPPC) and the electrochemical impedance spectroscopy (EIS) tests. The EIS test does not require expensive and complicated experimental equipment for high-capacity batteries and leads to no degradation compared to the HPPC test. However, the HPPC test is recommended by the battery test manual of the U.S. Department of Energy (FreedomCAR). Moreover, different profiles of dynamic current with regenerative braking are used for the validation of the estimated parameters for both charging and discharging procedures. Common dynamic cycles are the Federal urban driving schedule (FUDS), urban dynamometer driving schedule (UDDS), Dynamic Stress Test (DST), and Beijing Dynamic Stress test (BJDST).

The ECM parameters depend on the state of health (SoH), the state of charge (SoC), temperature, current intensity (C-rate), and current direction. The ECM parameter identification has many outlined methods because numerous parameters identification at each independent parameter led to a complex optimization problem. Examples of the parameter estimation methods are offline parameterized look-up tables along with online adaptive methods such as the dual Kalman filter algorithms and recursive least squares methods. Jackey et al. outlined a layered technique to decompose the parameter identification problem into stages for the ease and speed of parameters estimation. Hua et al. suggested a load-dependent method to smooth the parameters variation with temperature change by defining two independent parameter sets with higher accuracy at load and rest operations. Lia et al. compared nine ECMs and nine algorithms to find the best choice of parameter identification method for each ECM.

There have been numerous outlined metrics for thermal performance evaluation. However, until now there have been no clear metrics to accurately assess the performance of battery thermal management systems (BTMSs). Previous performance metrics are deeply discussed in section 6.1 below. The outlined methodology depends on normalized metrics to allow for comparison between cells with different geometries, design forms, and capacities. Moreover, absolute and normalized metrics are also outlined to assess the cell thermal system design and to estimate the required BTMS performance parameters.

Experimental setup is established to define the INR21700-50E cell characteristics using the HPPC test as described in 6.2 below. Afterwards, equation-based models are applied to define ECM parameters for cell behavior definition. Moreover, computational modeling using ANSYS fluent is utilized to identify cell thermo-electrochemical behavior. Afterwards, design exploration of all encountered design points and their resulted cell behavior are studied to develop and investigate the outlined metrics.

### 6.1 Metrics

### 6.1.1 Historical Overview

Recent cell thermal performance metrics for BTMSs could be classified into temperature-based and heat rate-based parameters. The temperature-based parameters target the definition of temperature extremes and distribution across cells such as the average temperature (T_{avg}), maximum temperature (Tₘₐₓ), maximum temperature difference (ΔTₘₐₓ), temperature uniformity, and temperature standard deviation. Other recently outlined parameters are those related to heat rate such as the cell cooling coefficient (CCC) (W/K) defined as the ratio of heat rate dissipated (Q_{diss}) (W) to the maximum temperature difference (K). Hales et al. outlined the CCC with a stringent experimental setup. Results revealed that the CCC values for 5 Ah and 7.5 Ah pouch cells are 0.985 W/K and 1.907 W/K respectively for single-sided surface cooling. Afterwards, Russel et al. outlined experimental setup enhancements for more accurate CCC estimations. Results showed a maximum variation of 36% between the estimated CCCs with previously reported values. CCC can be calculated using the following equation.

$$CCC = \frac{{Q}_{diss}}{Δ {T}_{max}} \qquad ( 2 )$$

For CCC capacity normalization, the per capacity coefficient (PCC) (W/K·Ah) is defined as the ratio of the CCC to the beginning of life capacity (BoL capacity) (Ah). The PCC is also a normalization of the number of layers because of the direct relation between layers number and the cell capacity. Li et al. found that typical values for single-sided surface cooling of recent prismatic cells are 0.02:0.06 W/K·Ah and for recent pouch cells are 0.6:0.7 W/K·Ah. Whereas typical values for tab cooling of recent pouch cells are 0.004:0.06 W/K·Ah. PCC can be calculated using the following equation.

$$PCC = \frac{CCC}{BoL capacity} \qquad ( 3 )$$

Furthermore, the cell cooling coefficient for geometry normalizations to aspect ratios (CCC_{GN-AR}) is defined by dividing the CCC by the heat transfer area (A) divided by the heat transfer length (L) for a normalization to the cell aspect ratio. Marzook et al. studied the negative tab cooling of 21700 and 18650 cells. The CCC for tab cooling was 0.115 W/K for 18650 cells which is lower compared to 0.139 W/K for 21700 cells. The CCC_{GN-AR}, on the other hand, was lower for 21700 cells by 5% compared to 18650 cells. CCC_{GN-AR} could be calculated utilizing the succeeding equation:

$${CCC}_{GN - AR} = \frac{CCC}{A / L} \qquad ( 5 )$$

The cell cooling coefficient for heat normalization (CCC_{HN}), on the other hand, is calculated by dividing the CCC to the heat generated at 50% SoC which is defined by the current intensity squared multiplied by Rₛ. Rₛ is defined by the instantaneous voltage drop in terminal voltage at 50% SoC and 25° C. Haram et al. compared the 5 Ah 21700-M50T cell with the 27.07 Ah 4680 Panasonic cells for both surface and tab cooling. Results revealed that the CCC_{HN} values for tab cooling are 0.164 W/K. Ah². Ω and 0.319 W/K. Ah². Ω for the 21700 and 4680 cells respectively. Whereas the CCC_{HN} values for surface cooling are 1.0105 W/K. Ah². Ω and 0.349 W/K. Ah². Ω for the 21700 and 4680 cells respectively. CCC_{HN} can be calculated by the following equation:

$${CCC}_{HN} = \frac{CCC}{{( {C}_{rate} \times Capacity )}^{2} {R}_{0}} \qquad ( 5 )$$

Another heat rate related parameter for modules is the module cooling coefficient (MCC). The MCC is computed by dividing the heat dissipated by the cooled region average temperature reduction between a BTMS and passive air cooling. Wang et al. investigated an active air cooling with 12 m/s flow stream velocity for cooling a battery module discharging at 2 C. Results revealed that the maximum temperature is approximately 43.9° C. and the range of the MCC for tab cooling is 0.1:0.2 W/K. MCC can be calculated using the following equation.

$${MCC}_{colled region} = \frac{{Q}_{diss}}{( {T}_{avg - BRMS} - {T}_{avg - passive air} ) {\vert}_{cooled region}} \qquad ( 6 )$$

Moreover, cooling energy efficiency coefficient (β) which could be defined like the coefficient of performance (COP) by dividing the heat dissipated by the power required for BTMSs. Lu et al. made a design exploration for defining the best thermal performance using the maximum temperature, the factor of space utilization rate for power density estimation, and the best power performance by the cooling energy efficiency coefficient (B). For a staggered arrangement, the ideal design point for 18650 cells was found to be 10 rows along the flow direction with a channel size of 1 mm. B is calculated utilizing the succeeding equation.

$$β = \frac{{Q}_{diss}}{{P}_{BTMS}} \qquad ( 7 )$$

### 6.1.2 Battery Thermal Performance Metrics

To effectively study a cell, interactions between chemical, electrical, and thermal behavior are divided into subsystems as described in FIG. 1. The thermo-electrochemical subsystem represents the conversion of stored energy to electrical energy and heat generation. The thermo-electrochemical subsystem treats the cell material as an active material with the trigger of a voltage difference applied as a driving force. Better thermo-electrochemical systems are recognized for higher percentages of electrical energy converted from stored energy. Afterwards, the cell thermal system represents cells as systems receiving the heat generated which is partially stored within the cell or dissipated towards the BTMS. Better cell thermal performance is recognized with higher heat dissipation. Despite the two cell subsystems are interactive, their separation is for clearly defined metrics for each system. Finally, the BTMS receives heat dissipation as an input which is partially removed towards the ambient as ambient heat dissipation.

Battery thermal performance is crucial because of the direct effects on short-term characteristics like discharge power and energy and long-term features like degradation. Therefore, different assessment metrics should be identified to successfully estimate cell thermo-electrochemical system performance. The comparison between the average heat rate generated and the average stored power available estimates electrical power and energy generated during discharge.

The average heat rate produced is calculated using the ECM average series resistance (Rₛ) estimated by the HPPC tests. The estimation of the heat generation and dissipation rates at 50% SoC, as previously outlined, is not quite accurate because the extremes of SoC working ranges have tremendous increases in terminal resistances for numerous cells. Therefore, all the outlined parameters are averaged through the entire cell working range. Afterwards, an average value of the open circuit voltage across the working SoC range is also estimated. Finally, the ratio of the heat rate generated to the available electrical power (P_{elec}) is defined as the heat generation ratio (HGR) as calculated in the following equation, which gives a crucial estimation of discharge efficiency considering the C-rate intensity.

$$HGR = \frac{{Q}_{gen}}{{P}_{elec}} = \frac{{I}^{2} {R}_{0}}{I {V}_{OC}} = \frac{I {R}_{0}}{{V}_{OC}} \qquad ( 8 )$$

The HGR could be calculated using 1 C-rate which broadens its usage as a cell discharge comparison metric for different cells. Moreover, cell electrical efficiency based on heat generation could be calculated by dividing the heat generation by the total power available (Pₜₒₜ) as follows.

$${η}_{elec} = \frac{{P}_{elec}}{{P}_{tot}} = \frac{{P}_{elec}}{{Q}_{gen} + {P}_{elec}} = \frac{I {V}_{OC}}{{I}^{2} {R}_{0} + I {V}_{OC}} = \frac{{V}_{OC}}{I {R}_{0} + {V}_{OC}} \qquad ( 9 )$$

Furthermore, to normalize the effect of capacity differences between cells, an independence on current should be imposed. Therefore, the normalized heat generation ratio (NHGR) (A⁻¹) is outlined to evaluate the heat generation normalized to cell capacities through the division by current as calculated in the following equation.

$$NHGR = \frac{HGR}{I} = \frac{R}{{V}_{OC}} \qquad ( 10 )$$

For the cell thermal system performance assessment, if the average of heat rate dissipated is divided by the average of maximum temperature difference, this gives rise to a new definition of the CCC (W/K) which resembles the reciprocal of the spatial thermal resistance. The new definition is like the previously discussed definition in Eq. 2. However, this definition of independent parameters makes the process of evaluating the CCC significantly easier than the previously outlined metric which required square charging and discharging pulses at 50% SoC for approximately 6 hours. The outlined CCC (W/K), on the other hand, is defined based on total surface area cooling through 1 C continuous discharge from 100% to 5% SoC to assess the integration of the total heat generation and dissipation through the entire working range and not for the 50% SoC only.

For geometry normalization, the CCC_{GN} (W/m²·K) is defined as the ratio of the CCC by the cell heat transfer area, which is similar to the well-known overall heat transfer coefficient.

$${CCC}_{GN} = \frac{CCC}{A} \qquad ( 11 )$$

This metric is different from the geometry normalized CCC previously outlined which multiplies the currently outlined definition by the cooling length. However, the previous metric targets the comparison of different cell aspect ratios which unfortunately led to a departure from the main heat transfer definitions unlike the outlined metric.

The cell thermal efficiency (ηₜₕ) is calculated by dividing the actual heat dissipated by the maximum heat dissipated which equals the heat generated. Therefore, ηₜₕ could be used as a cell thermal efficiency comparison metric.

$${η}_{th} = \frac{{Q}_{diss}}{{Q}_{gen}} \qquad ( 12 )$$

The outlined thermal efficiency is extremely useful to compare different cells of different capacities unlike the previously outlined metric, CCC_{HN}, which depends on cell capacities. Because ηₜₕ depends on the ratio of the heat dissipation and heat generation for the same cell at the same current intensity, the dependence on different cells current intensities at the same C-rate (1 C for the outlined metric) is normalized and eliminated. Therefore, cells of different capacities could be efficiently compared in terms of thermal performance using the outlined thermal efficiency normalized metric. Consequently, Higher values of ηₜₕ represent better cell thermal performance with ideal ηₜₕ equals to unity.

### 6.1.3 BTMS Selection Metrics

Appropriate thermal system selection is a decisive decision leading to desirable specific cell thermoelectrical operating conditions. Furthermore, the available heat dissipation rates are also defined by the selected BTMS. Consequently, the power input to the BTMS consumed from the battery capacity directly affects the overall system performance. Hence, for proper thermal system selection, three values should be identified:
1. The thermal system heat transfer area.
2. The heat dissipation flux required per unit maximum surface temperature difference is identified through the CCC_{GN} which is like the overall heat transfer coefficient.
3. The required heat dissipation rate for a predefined maximum temperature difference across the cell surface is defined by the CCC to assess the heat dissipation rate required.

To investigate the outlined methodology of thermal system selection, an ideal thermal objective needs to be identified as a test case. Therefore, an ideal design point (IDP) is outlined which has an ambient temperature of 25° C. as a standard ambient temperature. Moreover, a cooling temperature is higher than the ambient temperature by 3° C., for phase change temperatures (PCTs) consideration. Furthermore, a maximum temperature difference of 3° C. is chosen as recommended for low voltage unbalance regarding cell level. After applying the previous considerations, the maximum cell temperature equals 31 C. The purpose of this ideal design point is to estimate the just adequate cooling area required at the IDP (A_{IDP}) which is determined using the response surface methodology as an ideal strict objective. Therefore, the IDP is used as a standard objective depending on standard conditions as design parameters to generalize its use for all cells and applications. Moreover, CCC_{IDP} and CCC_{GN-IDP} could also be calculated to estimate the required heat rate and heat flux for the IDP.

To establish other cell thermal performance assessment indicators, the IDP is compared to the ideal case to assess the IDP requirements availability depending on the cell thermal design. The IDP aims for a partial cooling of the cell surface for lower BTMS requirements as will be discussed thoroughly in the section 6.3.2 below. Therefore, an area ratio (σ) discovers the availability of the required heat transfer area by comparing the A_{IDP} to the total cell surface area as calculated in the following equation. Despite the important σ definition, the heat transfer area is still the main comparison metric for different cells comparison because of the heat transfer concepts.

$$σ = {A}_{IDP} / A = {l}_{IDP} / l \qquad ( 13 )$$

Another comparison tool is established by dividing heat dissipation rate for the IDP (Q_{diss-IDP}) by the average heat rate generation to find the IDP thermal efficiency required (η_{th-IDP}). This indicates just adequate heat dissipation to make the cell at the IDP with minimum cooling power and energy. Unlike ηₜₕ, lower values of η_{th-IDP} indicate better cell thermal performance because it means that lower thermal efficiency is adequate to achieve the IDP requirements as calculated as follows.

$${η}_{th - IDP} = \frac{{Q}_{diss - IDP}}{{Q}_{diss}} \qquad ( 14 )$$

Furthermore, the thermal efficiency ratio (α) is defined as the ratio of the η_{th-IDP} to ηₜₕ. α is for the estimation of the IDP thermal efficiency compared to the total surface cooling case by using Q_{diss} at the total surface cooling case and not for the ideal, not existing, case as in η_{th-IDP} by using Q_{gen}. However, η_{th-IDP} is outlined to estimate the thermal efficiency compared to the cell ideal requirements as calculated as follows.

$$α = \frac{{η}_{th - IDP}}{{η}_{th}} = \frac{{Q}_{diss - IDP}}{{Q}_{diss}} \qquad ( 15 )$$

To summarize, A_{IDP}, CCC_{IDP}, and CCC_{GN-IDP} are the output of an efficient thermal system selection procedure. Using the IDP as a general ideal objective, the IDP thermal requirements could be compared to the ideal case to discover cell thermal design efficiency. Consequently, s and η_{th-IDP}, are utilized as other outlined cell thermal performance assessment metrics and to compare the IDP to the idealized cell case. Whereas a is used to compare the IDP to a real predefined case. Therefore, BTMS absolute requirements could be identified using the heat dissipation required at the IDP. This parameter achieves the ideal objective and represents the required heat dissipation as a performance parameter of the BTMS regardless of its type.

### 6.2. Methods

### 6.2.1 Cell Characteristics

The research conducted explored two different cylindrical cells: the INR21700-50E cell from SAMSUNG SDI Co. and the NCR18650PF cell from Panasonic. Cells characteristics are summarized in Table 3. These two well-known cells have the same chemistry and design form allowing for a clear assessment and comparison depending on the effect of different capacities and physical properties. Kollmeyer provided the NCR18650PF cell HPPC and continuous discharge tests at low temperatures of −20° C., −10° C., 0° C., 10° C., and 25° C. However, the data at 25° C. was only utilized because the current research focuses on moderate temperature operations. The INR21700-50E cell, on the other hand, is experimentally investigated at 25° C., 45° C., and 55° C. Afterwards, the UDDS cycle test is conducted at 25° C. only for thermoelectrical behavior validation.

TABLE 3
general characteristics of NCR18650PF and INR21700-50E cells.

| | NCR18650PF | INR21700-50E |
|---|---|---|
| Manufacturer | Panasonic | SAMSUNG SDI |
| Cathode material | NCA | NCA |
| BoL Capacity (Ah) | 2.9 | 4.9 |
| Cell diameter (mm) | 18 | 21.25 |
| Cell height (mm) | 65 | 70.8 |
| Mass (kg) | 48 | 69 |
| Cp (J/kg · K) | 678 | 885 |

6.2.2 Experimental investigation

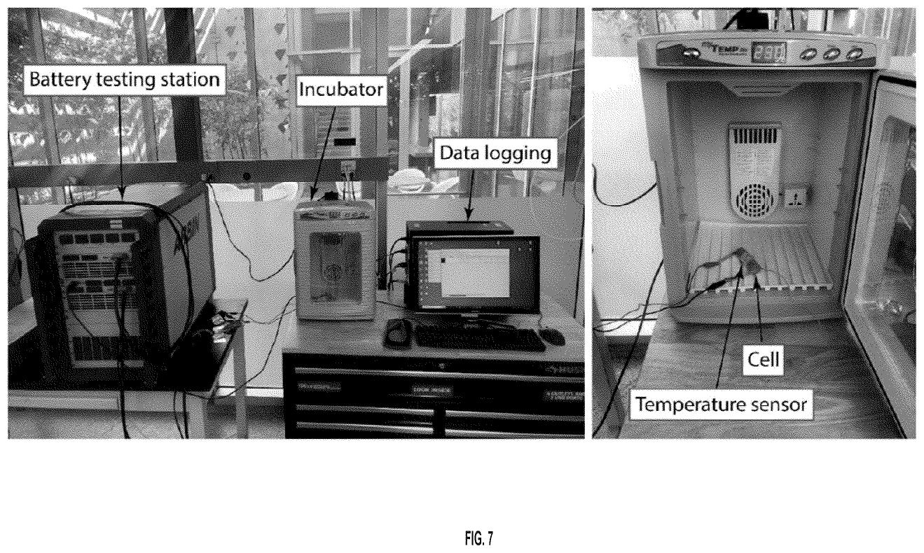

A brand new INR21700-50E cell was cycled using a BT-2000 Arbin battery testing station, model BT-M-40 in Arizona State University labs. The cell was tested at a constant ambient temperature using a digital incubator (MyTemp mini). Moreover, the temperature on the center of the cell surface was recorded using a PICO TC-08 datalogger with an accuracy of ±0.2% of the reading ±0.5° C. and a k-type thermocouple with an accuracy of ±0.4% of the reading. A demonstration of the experimental setup is depicted in FIG. 7.

During the research conducted, discharge was only regarded because charging results in lower heat generation. The following experimental procedures were performed to capture electrothermal behavior dependency on the state of charge (SoC) and temperatures:
1. Hybrid pulse power characteristic (HPPC) tests were performed with stringent steps for accurate behavior capture. To capture the electrical behavior at various SoCs, pulses of 72 s which results in 0.02% SoC reduction were applied. A long following rest period of 25 min for the first 30 pulses and 30 min for the last 20 pulses to accurately assess the open circuit voltage (V_{OC}). For an optimized data acquisition, small time steps of 0.1 s were used for pulse periods and the beginning of the rest periods where steep voltage gradients existed. Whereas the rest of the HPPC test has longer time steps of 1 s.
2. 0.5 C, 1 C, and 2 C continuous discharge tests were applied to observe thermal and electrical behaviors. Various discharge currents were used to validate the thermoelectrical behavior of the developed model for different current intensities.

For the electrical behavior definition at various temperatures, all tests were applied at 25° C., 45° C., and 55° C. constant ambient temperatures. The Coulomb counting method is adopted for the estimation of the SoC which requires an accurate initial definition of the SoC and high accurate ampere counting recorder. Moreover, a UDDS cycle was performed at 25° C. for thermoelectrical behavior validation purposes at actual dynamic driving cycles. The cell temperature does not change significantly during the HPPC tests. Therefore, considering that a single cell temperature equals the ambient temperature mainly defining the thermo-electrochemical behavior of cells for this test is a reasonable and applicable assumption. Continuous discharge tests, on the other hand, have significant cell temperature changes.

### 6.3. Modeling and Simulation

### 6.3.1 Equation-Based Model

Modeling was utilized for cell-level thermo-electrochemical behavior representation and the ease of numerous design explorations. The ECM was chosen as the best compromise for modeling complexity and computation cost. The 2RC ECM was then chosen to model cell thermo-electrochemical behavior. The 2RC ECM has accomplished a successful compromise between the low accuracy encountered by the 1RC ECM and the high computation cost suffered from the 3RC ECM. The terminal voltage of the 2RC ECM is calculated as follows:

$${V}_{t} = {V}_{OC} - {IR}_{s} - {V}_{1} - {V}_{2} \qquad ( 16 )$$

where V₁ and V₂ could be calculated from the following equations.

$$\frac{d {v}_{1}}{dt} = - \frac{1}{{R}_{1} {C}_{1}} {V}_{1} - \frac{1}{{C}_{1}} \qquad ( 17 )$$

$$\frac{d {v}_{2}}{dt} = - \frac{1}{{R}_{2} {C}_{2}} {V}_{2} - \frac{1}{{C}_{2}} \qquad ( 18 )$$

An electrothermal model, built by MATLAB 2023b software package, was developed to utilize the HPPC tests data to estimate the ECM parameters. The 2RC ECM electrical parameters (V_{OC}, Rₛ, R₁, R₂, C₁, and C₂) are identified against SoC and temperature variations. The thermal behavior, on the other hand, is mainly dependent on the Joule heating associated with Rₛ. The layered approach was utilized for parameter identification using the nonlinear least squares method of Levenberg Marquardt (LM). Afterwards, the thermoelectrical behavior was validated using a UDDS cycle at 25° C. and 0.5 C-rate, 1 C-rate, and 2 C-rate continuous discharge tests at 25° C. and 1 C-rate continuous discharge at 45° C. and 55° C. ambient temperatures. Due to the major changes in cells temperatures during continuous charge tests, cells electrothermal response for continuous discharge tests was identified by estimated parameters at multiple temperatures using lookup tables. Furthermore, accurate estimation of the induced heat transfer coefficient within the thermal chamber should be previously performed using the rest period followed by continuous discharge tests for accurate surrounding effect definition.

### 6.3.2 Computational Model

Battery analysis requires dealing with multiple domains such as cells and BTMSs along with multiple chemical and physical behaviors such as chemical, electrical and thermal interactions encountered in cells. Therefore, the multi-scale multi-domain (MSMD) approach is adopted for a comprehensive investigation of battery behavior. The thermo-electrochemical behavior could then be described using the following equations [42].

$$\frac{\partial {pC}_{p} T}{\partial t} - ∇ \cdot ( k ∇ T ) = {σ}_{+} {\vert ∇ {φ}_{+} \vert}^{2} + {σ}_{-} {\vert ∇ {φ}_{-} \vert}^{2} + {q}_{Ech} + {q}_{short} + {q}_{abuse} \qquad ( 19 )$$

$$∇ ( {γ}_{+} ∇ {φ}_{+} ) = - ( {j}_{Ech} = {j}_{short} ) \qquad ( 20 )$$

$$∇ ( {γ}_{-} ∇ {φ}_{-} ) = + ( {j}_{Ech} = {j}_{short} ) \qquad ( 21 )$$

where p, Cₚ, k, T, and t are the density, specific heat, thermal conductivity, temperature, and time, respectively. Whereas y₊ and y₋ are the electric conductivities of the positive and negative electrodes. φ₊ and φ₋ are the positive and negative electrodes phase potentials. Heat transfer rates due to electrochemical reactions, short circuits, and abuse operations are illustrated by q_{Ech}, qₛₕₒᵣₜ and q_{abuse}, respectively. Finally, j_{Ech} and jₛₕₒᵣₜ represents the current transfer rate due to the electrochemical reactions and short circuits, respectively.

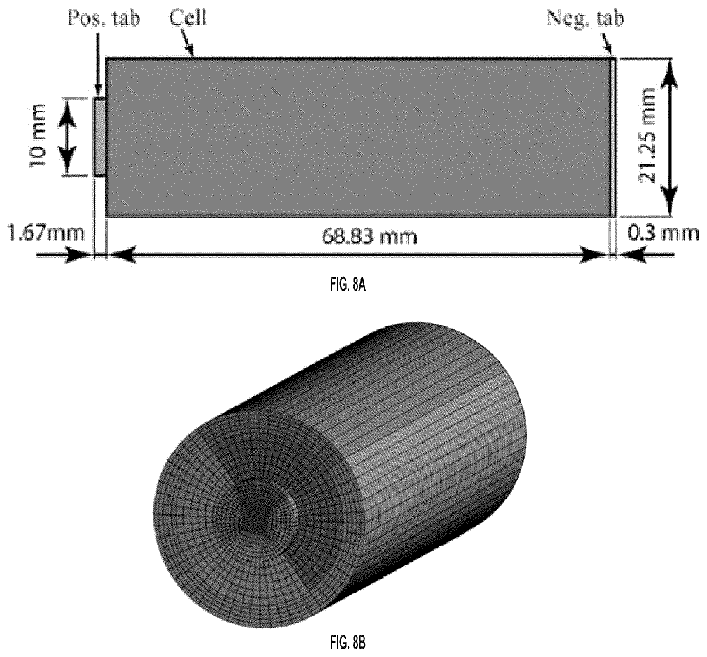

A cell domain was only utilized without any surroundings to simulate the thermo-electrochemical behavior of different cells using the ECM as depicted in FIG. 8A with material properties defined in Table 4. Therefore, different boundary conditions were employed to model the effects of different ambient conditions and thermal systems. A computational fluid dynamics (CFD) model was built using the ANSYS 2023R1 software package to investigate different boundary conditions and the effects of different thermal system design variations like cooling lengths on the cell spatial domain behavior. The model was validated using the UDDS and continuous discharge tests. An unstructured mesh was produced using ANSYS Meshing 23.1 software for cell domain discretization as shown in FIG. 8B. A fine mesh was produced to especially capture tabs geometrical details.

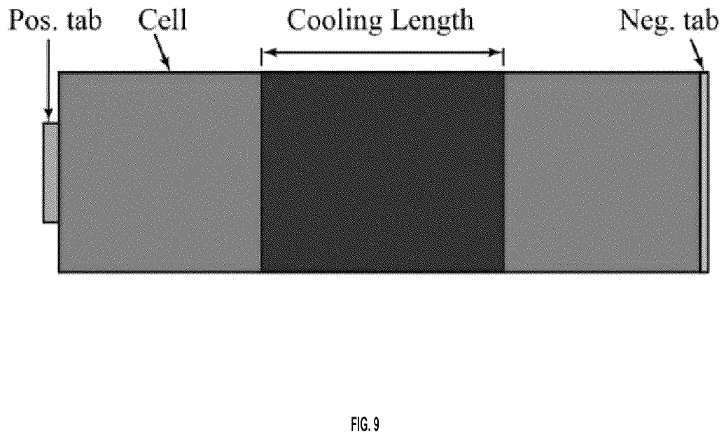

ANSYS Fluent 23.1 finite volume analysis software was then employed to utilize the 2RC ECM for the two investigated cells. The convergence is achieved for conservation equations and monitored parameters by reaching scaled residuals less than 10-5. For the validation cases, convective heat transfer boundary conditions were used for all cell surfaces. On the other hand, the constant temperature boundary conditions on a partial centered cooling surface were used for thermal system exploration as demonstrated in FIG. 9. The different exploited cell materials and dimensional parameters are summarized in Table 4. It is worth noting that an orthotropic material representation was utilized for cells active materials domains due to the presence of current collectors with high thermal conductivity within the cell active material.

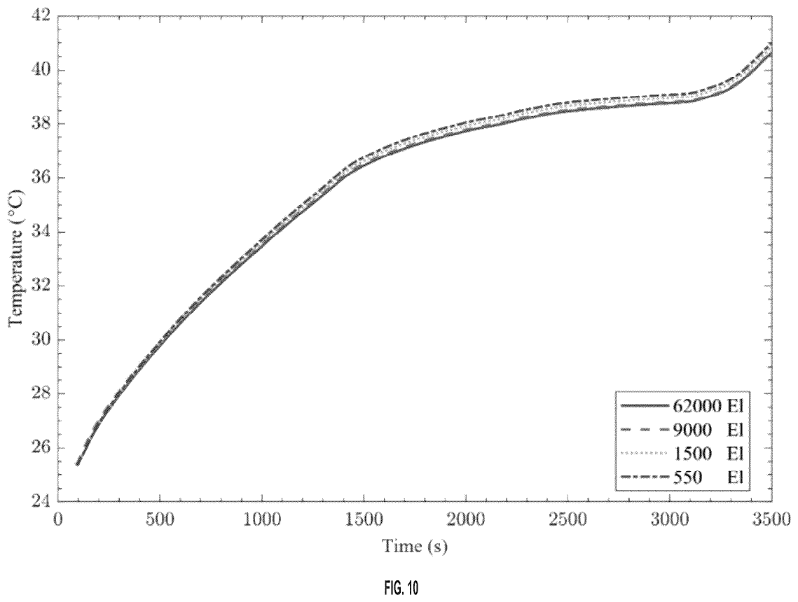

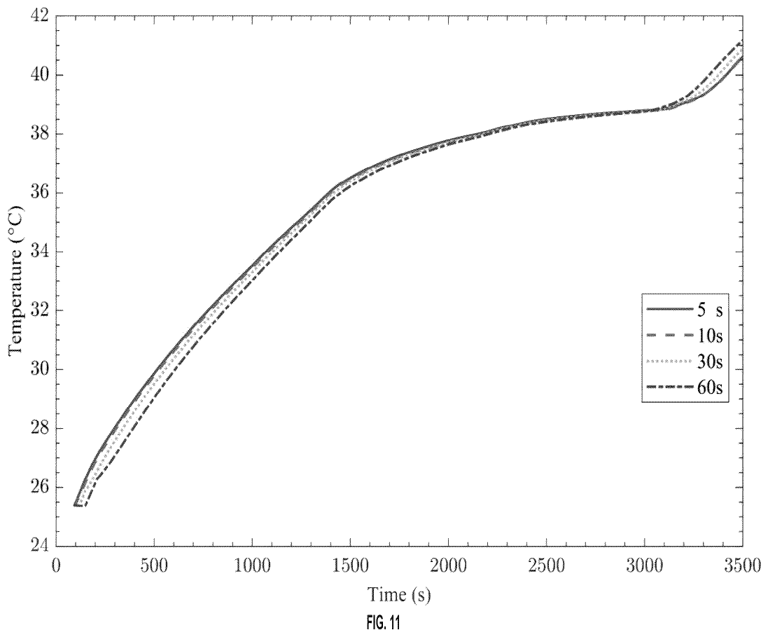

Afterwards, a mesh dependency study was performed to make sure of the independence of the simulated results on the geometrical discretization quality as shown in FIG. 10. Despite the insignificant dependence on the chosen number of elements. The 9000-element mesh was selected for the optimized dependency to capture the geometrical details, especially for the cell positive tab properly. FIG. 11, on the other hand, illustrates the effect of time steps on the produced results. A departure for the 30 s and 60 s time steps behaviors occur at the beginning and the end of the thermal behavior compared to the 5 s and 10 s time steps behaviors. The 10 s time step was chosen for the minimum time step dependency because 10 s time step behavior approximately coincides with the 5 s time step behavior.

TABLE 4
Thermophysical characteristics of cell and tab materials [44, 45].

| | NCR18650PF | | | INR21700-50E | |
|---|---|---|---|---|---|
| | Cell | Pos. tab | Neg. tab | Cell | Tabs |
| Density (kg/m3) | 2645 | 2719 | 8978 | 2540.4 | 8030 |
| Cp (J/kg · K) | 678 | 871 | 381 | 885 | 502.48 |
| K (W/m · K) | Kᵣ = 0.2, K_{z} = 30.4 | 202.4 | 387.6 | Kᵣ = 0.9, K_{z} = 24.2 | 78 |

### 6.3.3 Optimization

The design of experiment (DoE) targets the appropriate working conditions with minimum requirements by minimizing the BTMS weight and space represented by using a minimum cooling area. Moreover, minimum BTMS Power and energy is aimed by targeting a minimum cooling temperature and heat dissipated rate. A constant temperature boundary condition is employed for the cooling region which is an indicator for ideal thermal control of the heat transfer driving force which is temperature difference. The use of constant temperature is required as an ideal objective to assess battery performance regardless of the utilized BTMS performance. Additionally, a constant temperature boundary condition could be approximately achieved by using Peltier elements and PCMs. Moreover, the constant temperature boundary condition is an indicator of other thermal systems effectiveness and is also a necessity for the CCC estimation.

For the INR21700-50E, the maximum allowable intermittent discharge is 3 C and the maximum allowable continuous discharge is 2 C. Moreover, the maximum allowable charge current is 1 C and it is recommended to be 0.5 C. Continuous discharge is uncommon in real applications, and continuous charge is common. However, 1 C continuous discharge is chosen for the DoE because 1 C continuous charge is not recommended by the manufacturer and because of the higher heat generation associated with discharge. This will clearly distinguish between critical battery behaviors encountered, which is essential to assess BTMS performance under extreme conditions. Moreover, the cell was discharged to 5% SoC only to avoid accelerated degradation and for real applications consideration.

The response surface methodology (RSM) was then performed to assess different thermal system designs. The central composite design with the enhanced face-centered method was used to set the design of experiment points illustrated in Table 5. The chosen design parameters are the cooling temperature and the cooling length. On the other hand, the performance parameters chosen are the temperature related parameters of Tₘₐₓ and ∇Tₘₐₓ along with the heat related parameters of Q_{diss}, CCC, and CCC_{GN}. Moreover, refinement experiments were simulated to minimize the error between values from the predicted surface and the calculated ones using the Kriging algorithm with a variable kernel variation as demonstrated in Table 6.

TABLE 5
Experiment points for the INR21700-50E cell.

| | | | | Maximum | | | |
|---|---|---|---|---|---|---|---|
| | | | Maximum | surface | Heat | | |
| | Cooling | Cooling | surface | temperature | dissipation | | |
| | length | Temperature | temperature | difference | rate | CCC | CCC_{GN} |
| No. | (mm) | (K) | (K) | (K) | (W) | (W/K) | (W/m² · K) |
| 1 | 35 | 298.15 | 300.78 | 2.63 | −1.60 | −0.61 | −259.93 |
| 2 | 1 | 298.15 | 311.51 | 13.36 | −0.95 | −0.07 | −1064.18 |
| 3 | 18 | 298.15 | 301.81 | 3.66 | −1.47 | −0.40 | −333.75 |
| 4 | 69 | 298.15 | 299.98 | 1.83 | −1.69 | −0.93 | −201.22 |
| 5 | 52 | 298.15 | 300.23 | 2.08 | −1.67 | −0.80 | −231.63 |
| 6 | 35 | 288.15 | 290.84 | 2.69 | −1.65 | −0.61 | −262.65 |
| 7 | 35 | 293.15 | 295.84 | 2.69 | −1.65 | −0.61 | −262.66 |
| 8 | 35 | 308.15 | 310.36 | 2.21 | −1.35 | −0.61 | −260.35 |
| 9 | 35 | 303.15 | 305.57 | 2.42 | −1.48 | −0.61 | −261.18 |
| 10 | 1 | 288.15 | 302.97 | 14.82 | −1.05 | −0.07 | −1065.13 |
| 11 | 18 | 293.15 | 296.94 | 3.79 | −1.55 | −0.41 | −339.99 |
| 12 | 69 | 288.15 | 289.99 | 1.84 | −1.72 | −0.93 | −202.62 |
| 13 | 52 | 293.15 | 295.25 | 2.10 | −1.70 | −0.81 | −232.92 |
| 14 | 1 | 308.15 | 320.12 | 11.97 | −0.85 | −0.07 | −1064.12 |
| 15 | 18 | 303.15 | 306.55 | 3.40 | −1.37 | −0.40 | −336.46 |
| 16 | 69 | 308.15 | 309.67 | 1.52 | −1.40 | −0.92 | −200.11 |
| 17 | 52 | 303.15 | 305.06 | 1.91 | −1.53 | −0.80 | −231.01 |

TABLE 6
Refinement points for the INR21700-50E cell.

| | | | | Maximum | | | |
|---|---|---|---|---|---|---|---|
| | | | Maximum | surface | Heat | | |
| | Cooling | Cooling | surface | temperature | dissipation | | |
| | length | Temperature | temperature | difference | rate | CCC | CCC_{GN} |
| No. | (mm) | (K) | (K) | (K) | (W) | (W/K) | (W/m² · K) |
| 1 | 60.57 | 292.94 | 294.88 | 1.93 | −1.71 | −0.89 | −218.89 |
| 2 | 9.59 | 288.15 | 293.06 | 4.91 | −1.44 | −0.29 | −459.15 |
| 3 | 26.46 | 308.15 | 310.74 | 2.59 | −1.31 | −0.51 | −286.38 |
| 4 | 43.55 | 288.15 | 290.50 | 2.35 | −1.68 | −0.72 | −246.37 |
| 5 | 8.43 | 308.15 | 312.42 | 4.27 | −1.15 | −0.27 | −478.95 |
| 6 | 45.32 | 308.15 | 310.04 | 1.89 | −1.37 | −0.73 | −240.86 |
| 7 | 29.60 | 288.15 | 291.11 | 2.96 | −1.62 | −0.55 | −276.72 |
| 8 | 61.52 | 308.15 | 309.74 | 1.59 | −1.40 | −0.88 | −214.43 |
| 9 | 23.51 | 288.15 | 291.50 | 3.35 | −1.60 | −0.48 | −304.38 |
| 10 | 40.11 | 308.15 | 310.19 | 2.04 | −1.36 | −0.67 | −249.76 |
| 11 | 13.23 | 308.15 | 311.72 | 3.57 | −1.22 | −0.34 | −387.21 |
| 12 | 56.74 | 308.15 | 309.80 | 1.65 | −1.39 | −0.84 | −222.71 |
| 13 | 4.86 | 288.15 | 294.60 | 6.45 | −1.33 | −0.21 | −633.65 |
| 14 | 65.76 | 288.15 | 290.02 | 1.87 | −1.72 | −0.92 | −209.04 |
| 15 | 9.28 | 298.17 | 302.92 | 4.76 | −1.36 | −0.29 | −461.89 |
| 16 | 26.48 | 298.03 | 301.10 | 3.07 | −1.55 | −0.50 | −285.41 |
| 17 | 43.51 | 298.18 | 300.49 | 2.31 | −1.64 | −0.71 | −245.19 |
| 18 | 60.74 | 300.63 | 302.46 | 1.84 | −1.61 | −0.88 | −216.81 |
| 19 | 48.02 | 288.15 | 290.36 | 2.21 | −1.69 | −0.77 | −239.15 |
| 20 | 21.00 | 308.15 | 311.06 | 2.91 | −1.28 | −0.44 | −313.81 |
| 21 | 32.06 | 308.15 | 310.48 | 2.33 | −1.34 | −0.57 | −267.79 |
| 22 | 38.14 | 288.15 | 290.70 | 2.55 | −1.66 | −0.65 | −256.16 |
| 23 | 15.05 | 288.15 | 292.25 | 4.10 | −1.52 | −0.37 | −369.29 |
| 24 | 3.50 | 308.15 | 314.32 | 6.17 | −1.04 | −0.17 | −722.00 |
| 25 | 55.08 | 288.15 | 290.18 | 2.03 | −1.70 | −0.84 | −228.24 |
| 26 | 49.14 | 308.15 | 309.95 | 1.80 | −1.38 | −0.77 | −234.75 |
| 27 | 66.34 | 308.15 | 309.69 | 1.54 | −1.40 | −0.91 | −205.37 |
| 28 | 29.04 | 308.15 | 310.62 | 2.47 | −1.32 | −0.54 | −276.94 |
| 29 | 57.88 | 288.15 | 290.13 | 1.98 | −1.71 | −0.86 | −223.64 |
| 30 | 12.16 | 288.15 | 292.62 | 4.47 | −1.48 | −0.33 | −409.00 |
| 31 | 40.87 | 288.15 | 290.60 | 2.45 | −1.67 | −0.68 | −250.95 |
| 32 | 20.75 | 288.15 | 291.71 | 3.56 | −1.55 | −0.44 | −315.17 |
| 33 | 63.49 | 288.15 | 290.05 | 1.90 | −1.72 | −0.91 | −213.52 |
| 34 | 3.34 | 293.47 | 300.99 | 7.52 | −1.24 | −0.16 | −737.70 |
| 35 | 1.12 | 303.53 | 315.32 | 11.79 | −0.91 | −0.08 | −1035.33 |
| 36 | 68.87 | 302.70 | 304.39 | 1.69 | −1.56 | −0.92 | −201.02 |
| 37 | 64.82 | 294.86 | 296.74 | 1.88 | −1.72 | −0.91 | −210.93 |
| 38 | 59.58 | 302.75 | 304.53 | 1.78 | −1.55 | −0.87 | −218.60 |
| 39 | 3.96 | 304.72 | 310.84 | 6.12 | −1.11 | −0.18 | −685.14 |
| 40 | 17.08 | 292.46 | 296.34 | 3.88 | −1.54 | −0.40 | −348.59 |
| 41 | 67.06 | 304.70 | 306.34 | 1.64 | −1.50 | −0.92 | −204.42 |
| 42 | 68.22 | 292.83 | 294.68 | 1.85 | −1.72 | −0.93 | −204.22 |
| 43 | 1.70 | 302.78 | 312.26 | 9.48 | −0.99 | −0.10 | −920.72 |
| 44 | 60.94 | 299.31 | 301.19 | 1.87 | −1.65 | −0.88 | −216.60 |
| 45 | 5.52 | 293.32 | 299.43 | 6.12 | −1.34 | −0.22 | −593.20 |
| 46 | 30.07 | 306.25 | 308.75 | 2.50 | −1.38 | −0.55 | −273.92 |
| 47 | 1.31 | 290.66 | 303.09 | 12.43 | −1.08 | −0.09 | −996.98 |
| 48 | 43.49 | 293.16 | 295.51 | 2.35 | −1.68 | −0.72 | −246.45 |
| 49 | 43.32 | 303.20 | 305.33 | 2.13 | −1.51 | −0.71 | −244.85 |
| 50 | 40.69 | 290.02 | 292.47 | 2.45 | −1.67 | −0.68 | −251.24 |
| 51 | 26.96 | 293.03 | 296.15 | 3.12 | −1.60 | −0.51 | −285.98 |
| 52 | 11.18 | 303.00 | 307.13 | 4.14 | −1.29 | −0.31 | −417.42 |
| 53 | 24.52 | 302.74 | 305.70 | 2.96 | −1.43 | −0.48 | −295.89 |
| 54 | 12.16 | 294.51 | 298.99 | 4.47 | −1.47 | −0.33 | −405.78 |
| 55 | 30.20 | 301.10 | 303.82 | 2.73 | −1.51 | −0.55 | −274.44 |
| 56 | 7.29 | 292.69 | 298.16 | 5.47 | −1.40 | −0.26 | −523.97 |
| 57 | 1.85 | 291.91 | 302.14 | 10.23 | −1.13 | −0.11 | −898.04 |
| 58 | 34.08 | 296.25 | 298.98 | 2.73 | −1.65 | −0.60 | −264.75 |
| 59 | 68.72 | 303.88 | 305.53 | 1.65 | −1.53 | −0.92 | −201.17 |
| 60 | 50.47 | 306.54 | 308.36 | 1.82 | −1.43 | −0.78 | −232.94 |

The optimized design point was obtained by applying the multi-objective genetic algorithm (MOGA) to the response surfaces. The input parameters of the optimization study with their objectives are to minimize the constant cooling temperature and surface cooling length. Whereas those for the output are to minimize the maximum temperature, maximum temperature difference, and heat rate dissipation. During optimization, the consideration of constant cooling temperatures above the ambient by 3° C. is investigated to allow for the practical usage of phase change temperatures (PCTs).

### 6.4 Results and Discussion

6.4.1 Model validation

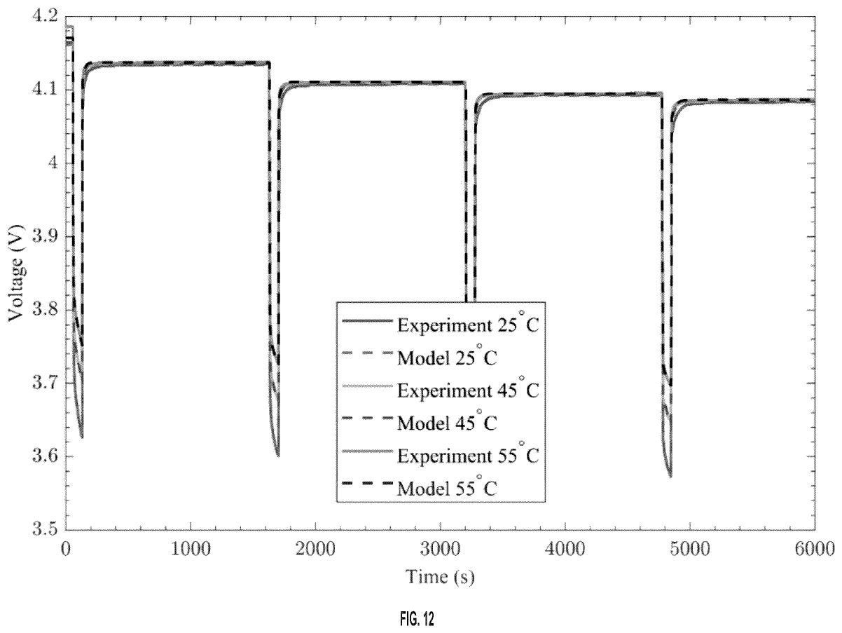

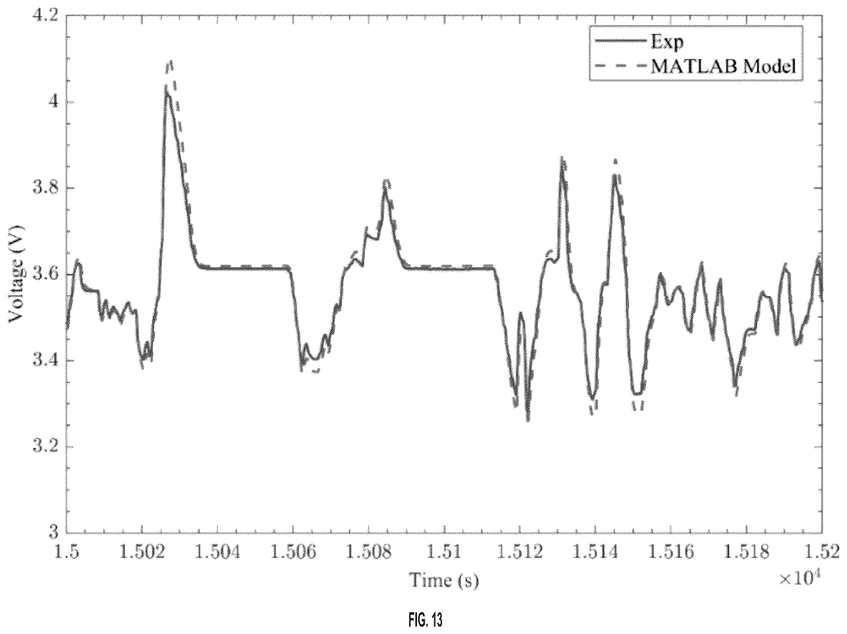

As described in section 6.2.2 above, The HPPC tests at 25° C., 45° C., and 55° C. are used to identify the ECM parameters for proper thermoelectrical behavior capture as illustrated in FIG. 12. As can be seen from the figure, there is a very good agreement between the model estimated output and the HPPC readings at all the investigated temperatures with a maximum relative error of about 8%. Moreover, the electrical behavior was validated using a UDDS cycle with a maximum relative error of 5% as shown in FIG. 13.

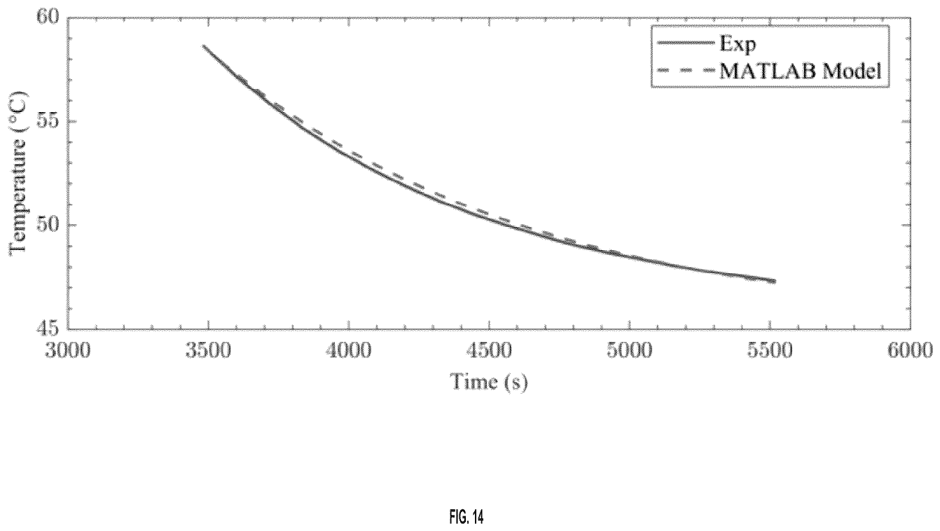

Afterwards, the model and experimental thermal behavior results of the rest period after a 1 C continuous discharge test were obtained and compared as illustrated in FIG. 14. Consequently, the heat transfer coefficient (HTC) could be estimated from the Newton law of heat transfer by convection. The HTC is estimated by the ratio of the average heat dissipated during cell cooling after discharge to the cell surface area multiplied by the temperature difference achieved. The induced HTCs by the utilized thermal chambers were 10.2 W/m²·K and 17.5 W/m²·K for the INR21700-50E and NCR18650PF cells, respectively. It is worth noting that those values present the combined convective and radiative HTCs. Herrara et al. experimentally estimated the combined HTCs value as 10.2 W/m²·K which is identical to the estimated HTC for the INR21700-50E cell.

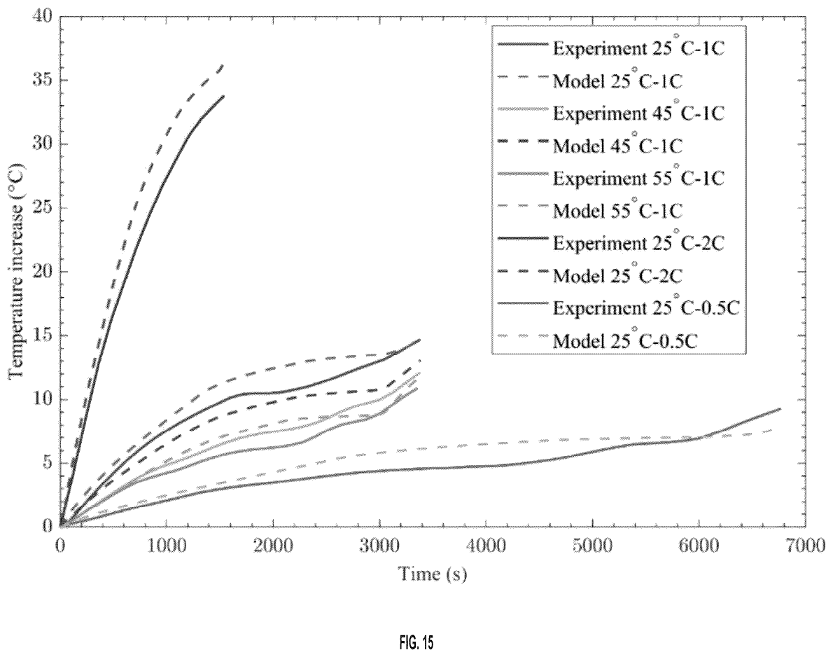

Furthermore, the ECM of MATLAB and ANSYS Fluent software packages were built using the HPPC experimental data collected as stated in section 6.2 above. Finally, the simulated thermal behavior predicted using the ECM was almost identical for the MATLAB model built as discussed in section 6.3.1 above and the ANSYS model overviewed in section 6.3.2 above at various current intensities and ambient temperatures. The results were then compared to the experimental results as shown in FIG. 15, with an estimated maximum relative error of 7% for continuous discharge during natural convection, and a maximum of less than 2° C. is noticed over the entire range. There are model overestimations of the temperature which can be reduced using higher RC branches. However, 2RC represents the best compromise of accuracy and computational cost for real-time estimation. Pizarro-Carmona et al. reported a minimum error reduction of only 0.02% through the utilization of 3RC instead of 2RC which justifies the adoption of 2RC ECM as the only used model in the current conducted work. This figure also demonstrates the great impact of cell discharge current on the heat generation and consequently the temperature increase.

### 6.4.2 Electrothermal Behavior

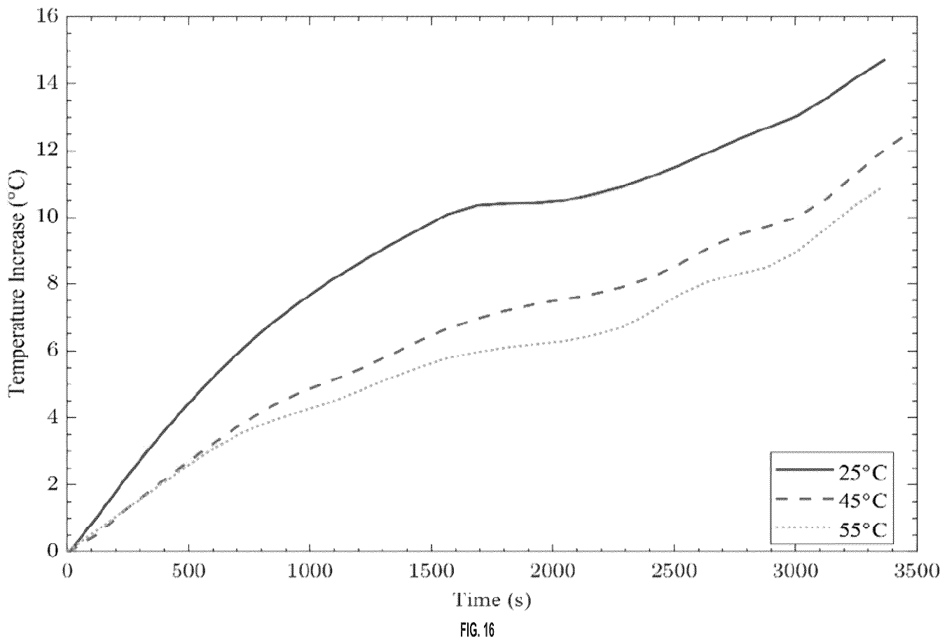

The cell's thermal and thermo-electrochemical systems are mutually entwined as depicted in FIG. 1. To establish this connection, the effects of thermal behavior on the cell electrochemical behavior should be investigated. The parameters of the ECM are identified using the method described in section 6.3.1 above. The estimated parameters have a valid range from 100% to 5% SoC and cell working temperatures from 25° C. to 55° C. by utilizing extrapolation methods for assessing behaviors beyond these ranges. Theoretically, the cell's internal resistance increases with the increase in operational temperature, thus increasing the heat generation. A major advantage of the INR21700-50E cell is the lower heat generation with higher cell temperatures represented by lower temperature increases as illustrated in FIG. 16. The figure represents the thermal performance of the INR21700-50E cell at 1 C continuous discharge at 25° C., 45° C., and 55° C. ambient temperatures. The temperature rise after continuous discharge at a 1 C rate in ambient temperatures of 25° C., 45° C., and 55° C. was 14.7° C., 12.4° C., and 10.9° C., respectively. Thus, raising the ambient temperature reduced the temperature increase at the end of 1 C continuous discharge by about 14%.

Thermal behavior could be further demonstrated using spatial temperature distributions within the cells. The layer-to-layer and in-layer thermal gradients clearly existed because of the high difference in the orthotropic thermal conductivity in radial and axial directions as summarized in Table 3. Consequently, fast degradation is attributable to temperature differences existence in layer-to-layer and in-layer regions.

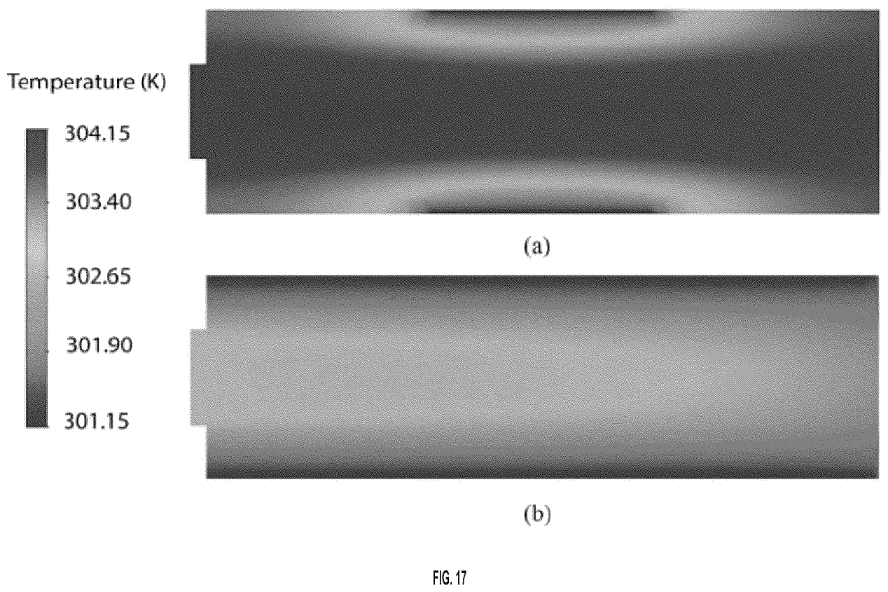

FIG. 17 compares the temperature contours between the IDP and the real case of a total surface cooling case at a 298.15K ambient temperature and a 301.15K cooling temperature for the INR21700-50E cell. The IDP temperature contour represents the ideal objective obtained by partial surface cooling, whereas the total surface cooling length represents an exaggerated superior performance with a predefined constant cooling temperature.

The IDP case results in similar low thermal gradients through both the negative and positive tabs regions. Although the negative tab is insulated, the total surface cooling results in high thermal gradient between the negative tab central and outer regions. This is due to the vicinity of the constant cooling temperature surface area and the negative tab with a high thermal conductivity. Furthermore, the negative tab connects heat efficiently from the active material through a relatively high axial orthotropic thermal conductivity to the cooling surface. Consequently, thermal gradients at the negative tab infers its contribution in heat dissipation during the total surface cooling case. This behavior suggests that tab cooling could have some advantages over surface cooling from a heat transfer point of view.

### 6.4.3 Cells Response Surfaces

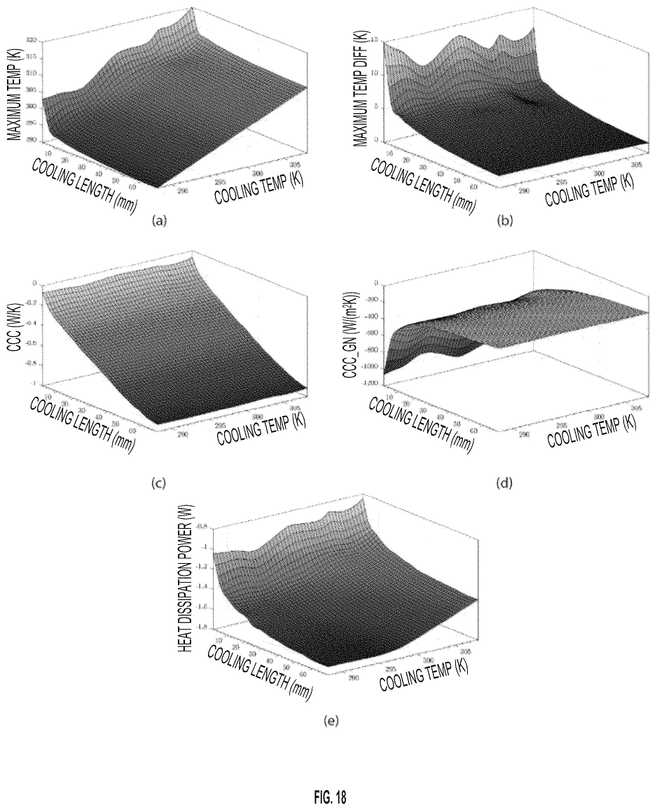

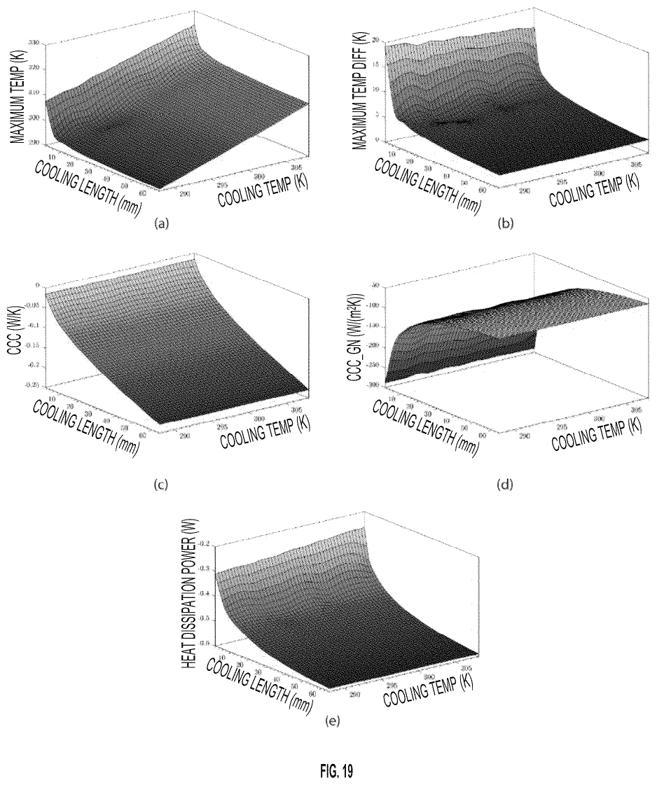

As previously described in section 6.3.3 above, the interaction between design and objective parameters could be identified through response surfaces for the investigated cells as shown in FIGS. 18 and 19 for the INR21700-50E cell and the NCR18650PF cell, respectively. The main design parameters are the cooling length and temperature, On the other hand, the objective output may be used to connect two main output parameters categories. Temperature related parameters such as maximum temperature and maximum temperature difference along with heat related parameters such as heat dissipation rate, CCC, and CCC_{GN}. As shown in FIGS. 18 and 19, the sensitivity of both the CCC and CCC_{GN} approximately are highly dependent on the cooling length. The maximum temperature mainly depends on the cooling temperature. However, the maximum temperature difference shows high dependency on the cooling length.

It can be also seen from the figures that after approximately 20% of the cooling length, the CCC, CCC_{GN}, and heat dissipation rate variation rates are significantly decreased, which justifies the sudden changes in maximum temperature and maximum temperature difference response surfaces at low cooling lengths. This is due to the fact that lower cooling lengths result in lower heat dissipation rates and higher maximum temperatures and maximum temperature differences due to the low cooling performance. Consequently, lower CCC values are attributed to lower cooling lengths but with higher CCC_{GN} values due to the low heat transfer areas. Due to the discrepancy between CCC and CCC_{GN} for assessing cell thermal systems, other metrics should be outlined to clearly characterize thermal performance as discussed in the following sections.

Moreover, the heat dissipation rate seems to have nearly constant values below 25° C. for large cooling lengths due to the constant heat generation below 25° C. This is estimated by using the nearest extrapolation method. The extrapolation was used because the data provided were only collected at 25° C., 45° C., and 55° C. More data is needed to verify this prediction. However, this study only focuses on moderate operating temperatures. Therefore, no uncertainty was encountered during thermal assessment procedures.

### 6.4.4 Battery Thermal Performance Assessment

Table 7 shows a complete overview of the metrics outlined as formerly discussed in sections 6.1.2 and 6.1.3. The first parameter to assess for a cell is the cell capacity as an assessment of electrochemical behavior, which is higher for the INR21700-50E cell by 69.97%. Furthermore, for cell thermo-electrochemical performance assessment, cell electrical efficiency and the cell thermal efficiency should be identified. It was found that the ratio of heat generation to the power available (HGR) for INR21700-50E cells is higher by 104% compared to the NCR18650PF which will be reduced to an increase by only 20.66% if a similar current was applied (NHGR). Consequently, the efficiency is lower for the INR21700-50E cell by 2.5%. Moreover, it should be recognized that the conducted comparison is at 1 C discharge for both cells, meaning that the INR21700-50E cell is discharged at a 69.97% higher current intensity. Therefore, the superiority of the cell thermo-electrochemical system for the NCR18650PF cell is noticed in terms of the efficiency for absolute and normalized values justified by its lower capacity.

On the other hand, for cell thermal system comparison, the cell thermal efficiency for the INR21700-50 cell is lower by 1.2% for the total surface cooling case with an ideal thermal system. This low difference favors the NCR18650PF cell maybe because of the greatly higher thermal conductivity for the NCR18650PF as represented in Table 4, which leads to higher heat dissipation as discussed in FIG. 17.

Furthermore, the thermal efficiency for both cells is close to unity which is a critical region due to the exponential behavior there. Moreover, the average of the maximum temperature difference is lower for the INR217000-50E by 16.2% which favors INR21700-50E cells considering the temperature related parameters. Therefore, other thermal performance metrics should be included for a fair comparison.

Moreover, the INR21700-50E has more heat generation and lower electrical efficiency justified by the higher capacity. Therefore, any comparison based on the previous parameters is unfair regarding the cell thermal system separately. Consequently, higher absolute BTMS requirements should be adopted represented by higher CCC_{IDP} and CCC_{GN-IDP} values. Therefore, normalization of the CCC to the heat generation is required for a fair comparison of the cell thermal system separately. Consequently, the IDP efficiency compared to the ideal (η_{th-IDP}) and real (α) cases are required and found to be lower for the INR21700-50E by 8.5% and 7.4%, respectively. Therefore, the superiority of the INR2170-50E cell thermal system is achieved because lower values of ηₜₕ-IPD and a indicate better performance.

Moreover, the σ and the η_{th-IDP} are 36% and 87.7%, respectively for the INR21700-50E cell, which implies that only these percentages are required compared to the ideal case to achieve the IDP. In other words, the INR21700-50E cell requires a lower ratio of its ideal normalized heat transfer rate to reach the IDP. Moreover, the area required for the IDP is lower for the INR21700-50E cell by 36.44%. Therefore, a superiority for the INR21700-50E is recognized in terms of all normalized heat dissipation requirements. Furthermore, the average of the maximum temperature difference for the IDP is higher by 24.3% for the INR21700-50E cell which is a disadvantage in temperature-related thermal performance parameters. However, operating at a higher average maximum temperature difference with the same desired maximum temperature difference (3K) made the INR21700-50E cell have superior heat-related performance parameters.

In conclusion, complete superiority for the INR21700-50E cell is noticed for normalized metrics of cell thermal system performance and consequently in normalized BTMS requirements. On the other hand, the NCR18650PF is better in the thermo-electrochemical system metrics due to its lower capacity.

### 6.4.5 BTMS Selection

The adoption of an ideal thermal system with total surface cooling led to an exaggerated superior thermal performance with approximately one degree of maximum temperature difference. For identifying the just adequate thermal system requirement for different cells, the IDP is used as an ideal objective design point. Therefore, the outlined IDP is utilized to select the ideal BTMS and produce other thermal performance assessment metrics for thermal performance comparison for both cells.

The results show that the INR21700-50E cell requires lower length by 46.16%, lower σ by 50%, and lower area by 36.44% compared to the NCR18650PF cell to reach IDP status and consequently requires less space and volume for the BTMS. The difference between length and area ratios exists due to the difference in cells diameters. On the other hand, the required CCC_{GN-IPD}, which resembles the overall heat transfer coefficient, for the INR21700-50E is higher by 303% compared to the NCR18650PF, which implies that higher heat dissipation rate and energy are required for the ideal BTMS.

To summarize, the comparison of heat transfer area favors the INR21700-50E cell, and the comparison based on the CCC_{GN-IDP} favors the NCR18650PF due to its lower capacity. Therefore, the integration of both requirements of CCC_{GN-IDP} and heat transfer area for the INR21700-50E cell led to a 156% higher CCC_{IDP} and a 218% higher heat dissipation rate compared to those of the NCR18650PF cells. In other words, the INR21700-50E cell needs higher absolute overall BTMS requirements at 1 C justified by higher current intensities.

The absolute metrics at the IDP such as A_{IDP}, CCC_{GN-IDP}, CCC_{IDP}, Q_{diss-IDP} do not have the same preference for INR21700-50E and NCR18650PF cells because of the variation in capacities, geometries, and thermo-electrochemical performance. However, Q_{diss-IDP} is the output of the BTMS selection and other metrics such as area and HTC required are tailored depending on other constraints like volume and weight required which are beyond the scope of the current study. Moreover, to fairly judge the thermal performance, a normalized metric is needed which is ηₜₕ. If the thermal efficiency is approximate to unity, η_{th-IDP} should be adopted as in our case to fairly judge and compare different cells.

Therefore, to represent the cell overall thermal performance in the fewest number of normalized metrics, the thermo-electrochemical performance should be represented by the NHGR, and the cell thermal performance should be identified by ηₜₕ with constraints on utilizing for comparison purposes. On the other hand, η_{th-IDP} and α are the essential normalized metric for comparison purposes for both BTMS evaluation and cell thermal performance assessment. Moreover, Q_{diss-IDP} is the crucial absolute metric for BTMSs identification.

The outlined methodology for BTMS selection begins with the identification of heat generation and η_{th-IDP} leading to the evaluation of the heat dissipation rate required by the BTMS for the IDP. Afterwards, depending on other design constraints, the area and heat dissipation flux required to achieve the previously determined heat transfer rate will be selected.

TABLE 7
A summary of the two cells metrics

| | |
|---|---|
| NCR18650PF | INR21700-50E |

General Inf.

| | | |
|---|---|---|
| D (m) | 0.018 | 0.021 |
| L (m) | 0.065 | 0.070 |
| Capacity (Ah) | 2.900 | 4.900 |
| R₀₋ₐᵥₑ (Ω) | 0.032 | 0.039 |
| V_{OC-ave} (V) | 3.709 | 3.746 |
| A (m²) | 3.68E−03 | 4.67E−03 |
| Q_{gen} (W) | 0.272 | 0.945 |
| HGR | 0.025 | 0.051 |
| η_{elec} | 0.975 | 0.951 |
| NHGR (A⁻¹) | 0.009 | 0.011 |

Total surface cooling case

| | | |
|---|---|---|
| ΔTₘₐₓ (K) | 1.174 | 0.983 |
| Q_{diss} (W) | 0.264 | 0.909 |
| CCC (W/K) | 0.225 | 0.925 |
| CCC_{GN} (W/m² · K) | 61.315 | 197.863 |
| ηₜₕ | 0.973 | 0.962 |

IDP case

| | | |
|---|---|---|
| l (m) | 0.047 | 0.025 |
| A_{IDP} (m²) | 2.65E−03 | 1.68E−03 |
| σ_{IDP} | 0.721 | 0.360 |
| ΔTₘₐₓ (K) | 1.403 | 1.744 |
| Q_{diss-IDP} (W) | 0.261 | 0.829 |
| CCC_{IDP} (W/K) | 0.186 | 0.476 |
| CCC_{GN-IDP} (W/m² · K) | 70.105 | 282.469 |
| η_{th-IDP} | 0.959 | 0.877 |
| α | 0.985 | 0.9126 |

### 6.6 Discussion

Due to the shortage of a clear methodology for defining cell performance and consequently BTMSs requirements, a methodology based on outlined absolute and normalized metrics is explored using experimental and theoretical studies. A 2RC equivalent circuit model (ECM) was built using ANSYS Fluent and MATLAB software packages. The 2RC ECM parameters are estimated and validated using HPPC, UDDS, and continuous discharge tests at various temperatures and current intensities. The INR21700-50E and NCR18650PF cells are studied during the conducted investigation. Moreover, response surfaces are built for design exploration and the interaction investigation of the cooling length and cooling temperature design parameters on the outlined output parameters. Absolute and normalized metrics to cell capacities are outlined for cell thermo-electrochemical behavior, cell thermal performance evaluation, and BTMS requirements.
The INR21700-50E cell has a higher capacity of 69.97% which caused a higher normalized heat generation ratio (NHGR) by 20.66% compared to the NCR18560PF cell. Therefore, the thermo-electrochemical performance of the INR21700-50E cell is worse compared to the NCR18560PF cell.
Normalized thermal performance for the total length cooling with ideal objectives led to ηₜₕ for the INR21700-50E cell of 96.2% which is approximately equal to that of the NCR18560PF cell indicating good cell thermal performance for both cells.
Normalized thermal performance metrics for the IDP compared to the ideal (η_{th-IDP}) and real (α) cases are lower by 8.5% and 7.4% for the INR21700-50E cell emphasizing its normalized superiority.
Absolute metrics are required to define BTMS requirements for the ideal objectives defined by the IDP, Q_{diss-IDP} is higher for the INR21700-50E cell by 218% compared to the NCR18560PF cell because the requirements are absolute at 1 C for cells of different geometries and capacities.

The outlined method could clearly assess the cell performance and BTMSs requirements. Therefore, the consideration of reporting the outlined metrics in cell manufacturer datasheets is considered of great importance. Additionally, the outlined metrics should be further utilized for numerous cells of different design parameters such as chemistries, capacities, design forms, and dimensions to profoundly understand the relation between design parameters and the outlined performance parameters. Furthermore, the outlined methodology of thermal performance assessment and thermal system selection for batteries should be further generalized for other systems with thermal behavior interactions with other physical and chemical behaviors. An example of future targeted systems is solar systems with thermal, electrical, and chemical interactions. Moreover, developing metrics for the incorporation of degradation effects will broaden the outlined metric credentials.

### 7. Additional Embodiments: Operational BTMS Performance and Real Thermal Efficiency

This section outlines connection between the thermoelectric generator figure of merit (Z) and to the battery electrical efficiency (η_{elec}).

### 7.1 Real Thermal Efficiency

BTMS requirements could be evaluated through performance metrics such as the required heat dissipation rate (Q_{diss}). Moreover, ideal BTMS performance was identified through maintaining the BTMS cooling surface to be at a constant temperature higher than the 25° C. ambient temperature by 3° C. Additionally, the maximum cell temperature difference is set to 3° C. higher than the cooling surface to minimize voltage and capacity imbalance. Consequently, the ideal design point (IDP) thermal efficiency (η_{th-IDP}) performance parameter was defined to account for the aforementioned cell BTMS requirements.

$${η}_{th - IDP} = {Q}_{diss - IDP} / {Q}_{gen} \qquad ( 22 )$$

Where Q_{diss-IDP} is the heat dissipation rate required to maintain a cell and a BTMS at the IDP conditions and Q_{gen} is the cell heat generation at the end of 1 C of discharge.

The previous metric is an ideal performance to represent the required BTMS requirements for a specific cell at normal operations, best represented at 1 C of discharge. However, to investigate real BTMSs based on different BTMS design parameters and operational conditions, another real thermal efficiency (ηₜₕ₋ᵣₑₐₗ) is outlined based on the average values of heat transfer rates defined as following.

$${η}_{th - real} = {Q}_{diss - real} / {Q}_{gen} = 1 - {Q}_{cell - stored} / {Q}_{gen} \qquad ( 23 )$$

Where Q_{diss-real} is the average heat dissipated through a BTMS and Q_{cell-stored} is the stored heat in a cell which is represented by the cell average temperature. Through the adoption of AI model, the cell surface temperature could be related to the cell average temperature. Consequently, the BTMS efficiency could be directly measured using the cell surface temperature. Therefore, ηₜₕ₋ᵣₑₐₗ could efficiently normalize the maximum temperature as a thermal performance parameter to indicate BTMSs thermal performance independent of cell capacity and applied current.

### 7.2 Battery Figure of Merit

A key performance metric of thermoelectric applications, such as thermoelectric generators, heaters, and coolers, is defined by the dimensionless figure of merit (Z), which is estimated as follows.

$$ZT = {S}^{2} σ T / K \qquad ( 24 )$$

where Z is the dimensional figure of merit (K⁻¹), S is the Seebeck coefficient, σ is the electrical conductivity, K is the total thermal conductivity, and T is the absolute temperature. Additionally, the maximum efficiency of the thermoelectric generator, working between a hot temperature (Tₕ) and a cold temperature (T_{c}), is defined as follows:

$${η}_{max} = \frac{( {T}_{h} - {T}_{c} )}{{T}_{h}} \times \frac{( \sqrt{1 + \overline{Z} \overline{T}} - 1 )}{( \sqrt{1 + \overline{Z} \overline{T}} + \frac{{T}_{c}}{{T}_{h}} )} \qquad ( 25 )$$

The basic concept of the dimensional figure of merit (Z) is to collect all material properties affecting efficiency, except for the operational parameters.

The battery electrical efficiency (η_{elec}), on the other hand, is defined as follows.

$${η}_{elec} = \frac{{V}_{OC}}{I {R}_{0} + {V}_{OC}} = \frac{1}{I \frac{{R}_{0}}{{V}_{OC}} + 1} = \frac{1}{I NHGR + 1} \qquad ( 26 )$$

The Normalized Heat Generation Ratio (NHGR) (A⁻¹) metric, defined as the ratio of series resistance (R₀) to the open-circuit voltage (V_{OC}), serves the same purpose as the dimensional thermoelectric generator figure of merit (Z) by collecting the material properties. Therefore, the only parameter left in η_{elec} is the operational parameter, the current (I). Consequently, the NHGR could be considered a key battery performance metric.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A computer-implemented method, comprising:
(a) constructing an equivalent circuit model of a battery based on battery characterization data comprising hybrid pulse power characterization (HPPC) data and continuous discharge data collected during test operation of the battery;
(b) accessing prescribed thermal limit data for the battery during discharge with respect to cooling by a battery thermal management system (BTMS), the prescribed thermal limit data comprising:
(i) a maximum allowable battery surface temperature, and
(ii) a maximum allowable temperature difference across a battery surface of the battery;
(c) generating, for each of a plurality of combinations of BTMS parameters including (i) a cooling temperature setpoint and (ii) a cooled-surface cooling length of the battery, thermal response values for the battery using the equivalent circuit model and a cooling boundary condition target defined by the BTMS parameters;
(d) generating, from the thermal response values generated using the equivalent circuit model, a mapping that relates the BTMS parameters to at least a battery surface maximum temperature and a battery surface temperature difference;
(e) transforming, based on the mapping, the prescribed thermal limit data into at least one target BTMS parameter value for at least one BTMS parameter of the BTMS; and
(f) generating, using measured temperature data measured at the battery surface, one or more control signals that set the at least one BTMS parameter to the at least one target BTMS parameter value.

2. The computer-implemented method of claim 1, wherein the cooling boundary condition target is a constant-temperature cooling boundary condition target that maintains a cooled portion of the battery surface at a constant temperature having a value equal to the cooling temperature setpoint along a length having a value equal to the cooled-surface cooling length.

3. The computer-implemented method of claim 2, wherein the cooling temperature setpoint and the cooled-surface cooling length are selected such that the cooled portion of the battery surface is a centered portion of the battery surface.

4. The computer-implemented method of claim 1, wherein generating the thermal response values comprises selecting the plurality of combinations of the BTMS parameters using a central composite design.

5. The computer-implemented method of claim 4, wherein the central composite design is a face-centered central composite design.

6. The computer-implemented method of claim 1, wherein generating the mapping comprises:
(i) selecting one or more refinement combinations of the BTMS parameters;
(ii) generating additional thermal response values for the one or more refinement combinations; and
(iii) reducing an error between predicted values produced by the mapping and calculated values represented by the additional thermal response values using a Kriging algorithm.

7. The computer-implemented method of claim 1, further comprising transforming, based on the mapping and the thermal response values, the prescribed thermal limit data into a required heat dissipation rate to be provided by the BTMS.

8. The computer-implemented method of claim 7, wherein the at least one target BTMS parameter value is selected based on the required heat dissipation rate.

9. The computer-implemented method of claim 7, wherein the required heat dissipation rate is a minimum heat dissipation rate that maintains the battery surface maximum temperature below the maximum allowable battery surface temperature and maintains the battery surface temperature difference below the maximum allowable temperature difference across the battery surface.

10. The computer-implemented method of claim 1, the equivalent circuit model being a two-RC-branch equivalent circuit model.

11. A system, comprising:
a processor in communication with a memory and a battery system, the memory including instructions executable by the processor to:
(a) construct an equivalent circuit model of a battery based on battery characterization data comprising hybrid pulse power characterization (HPPC) data and continuous discharge data collected during test operation of the battery;
(b) access prescribed thermal limit data for the battery during discharge with respect to cooling by a battery thermal management system (BTMS), the prescribed thermal limit data comprising:
(i) a maximum allowable battery surface temperature, and
(ii) a maximum allowable temperature difference across a battery surface of the battery;
(c) generate, for each of a plurality of combinations of BTMS parameters including (i) a cooling temperature setpoint and (ii) a cooled-surface cooling length of the battery, thermal response values for the battery using the equivalent circuit model and a cooling boundary condition target defined by the BTMS parameters;
(d) generate, from the thermal response values generated using the equivalent circuit model, a mapping that relates the BTMS parameters to at least a battery surface maximum temperature and a battery surface temperature difference;
(e) transform, based on the mapping, the prescribed thermal limit data into at least one target BTMS parameter value for at least one BTMS parameter of the BTMS; and
(f) generate, using measured temperature data measured at the battery surface, one or more control signals that set the at least one BTMS parameter to the at least one target BTMS parameter value.

12. The system of claim 11, the cooling boundary condition target being a constant-temperature cooling boundary condition target that maintains a cooled portion of the battery surface at a constant temperature having a value equal to the cooling temperature setpoint along a length having a value equal to the cooled-surface cooling length.

13. The system of claim 12, the memory further including instructions executable by the processor to:
select the cooling temperature setpoint and the cooled-surface cooling length such that the cooled portion of the battery surface is a centered portion of the battery surface.

14. The system of claim 11, the memory further including instructions executable by the processor to:
select the plurality of combinations of the BTMS parameters using a central composite design.

15. The system of claim 14, the central composite design being a face-centered central composite design.

16. The system of claim 11, the memory further including instructions executable by the processor to:
(i) select one or more refinement combinations of the BTMS parameters;
(ii) generate additional thermal response values for the one or more refinement combinations; and
(iii) reduce an error between predicted values produced by the mapping and calculated values represented by the additional thermal response values using a Kriging algorithm.

17. The system of claim 11, the memory further including instructions executable by the processor to:
transform, based on the mapping and the thermal response values, the prescribed thermal limit data into a required heat dissipation rate to be provided by the BTMS.

18. The system of claim 17, the at least one target BTMS parameter value being selected based on the required heat dissipation rate.

19. The system of claim 17, the required heat dissipation rate being a minimum heat dissipation rate that maintains the battery surface maximum temperature below the maximum allowable battery surface temperature and maintains the battery surface temperature difference below the maximum allowable temperature difference across the battery surface.

20. One or more non-transitory computer-readable medium having computer-readable instructions stored therein which, when executed by one or more processors, cause the one or more processors to:
(a) construct an equivalent circuit model of a battery based on battery characterization data comprising hybrid pulse power characterization (HPPC) data and continuous discharge data collected during test operation of the battery;
(b) access prescribed thermal limit data for the battery during discharge with respect to cooling by a battery thermal management system (BTMS), the prescribed thermal limit data comprising:
(i) a maximum allowable battery surface temperature, and
(ii) a maximum allowable temperature difference across a battery surface of the battery;
(c) generate, for each of a plurality of combinations of BTMS parameters including (i) a cooling temperature setpoint and (ii) a cooled-surface cooling length of the battery, thermal response values for the battery using the equivalent circuit model and a cooling boundary condition target defined by the BTMS parameters;
(d) generate, from the thermal response values generated using the equivalent circuit model, a mapping that relates the BTMS parameters to at least a battery surface maximum temperature and a battery surface temperature difference;
(e) transform, based on the mapping, the prescribed thermal limit data into at least one target BTMS parameter value for at least one BTMS parameter of the BTMS; and
(f) generate, using measured temperature data measured at the battery surface, one or more control signals that set the at least one BTMS parameter to the at least one target BTMS parameter value.
